(19) United States
(12) Patent Application Publication
(10) Pub. No.: US 2026/0261264 A1
(43) Pub. Date: Sep. 3, 2026

(54) METHODS AND APPARATUS TO GENERATE CLOCK SIGNALS USING SAMPLER-BASED PHASE DETECTION

(71) Applicant: Texas Instruments Incorporated, Dallas, TX (US)

(72) Inventors: Karthikeyan Gunasekaran, Chennai (IN); Sudarshan Varadarajan, Bangalore (IN); Jagannathan Venkataraman, BANGALORE (IN); Shraman Mukherjee, Bangalore (IN)

(21) Appl. No.: 19/067,440

(22) Filed: Feb. 28, 2025

(51) Int. Cl. H03L 7/091; H03L 7/083; H03L 7/099

(52) U.S. Cl. CPC H03L 7/091; H03L 7/083; H03L 7/0992

(57) ABSTRACT

An example apparatus includes sampler circuitry having a first input to receive a reference clock signal (CLKM_REF) a second input to receive a feedback clock signal (CLKB_FBK), and an output, transconductor circuitry having an input coupled to the output of the sampler circuitry and having an output, filter circuitry having an input coupled to the output of the transconductor circuitry and having an output, voltage controlled oscillator (VCO) circuitry having an input coupled to the output of the filter circuitry and having an output, and frequency divider circuitry an input coupled to the output of the VCO circuitry and having an output coupled to the second input of the sampler circuitry.

### TECHNICAL FIELD

This description relates generally to clock signals and, more particularly, to generate clock signals.

### BACKGROUND

With continuing advancements in electronic design, incentives to create flexible clock generation circuitry continue to increase. In some devices, clock generation circuitry needs to be capable of generating a plurality of clock signals. Some such clock generation circuitry generates each of the plurality of clock signals with different frequencies.

### SUMMARY

First example phase locked loop (PLL) circuitry comprises sampler circuitry having a first input to receive a reference clock signal (CLKM_REF) a second input to receive a feedback clock signal (CLKB_FBK), and an output, transconductor circuitry having an input coupled to the output of the sampler circuitry and having an output, filter circuitry having an input coupled to the output of the transconductor circuitry and having an output, voltage controlled oscillator (VCO) circuitry having an input coupled to the output of the filter circuitry and having an output, and frequency divider circuitry having an input coupled to the output of the VCO circuitry and having an output coupled to the second input of the sampler circuitry.

Second example phase locked loop (PLL) circuitry comprises sampler circuitry having a first input to receive a reference clock signal (CLKM_REF), a second input to receive a feedback clock signal (CLKB_FBK), and an output, transconductor circuitry having an input coupled to the output of the sampler circuitry and having an output, auxiliary phase frequency detector (AUX PFD) circuitry having a first input to receive the reference clock signal, a second input to receive the feedback clock signal, and an output, reduced charge pump (RCP) circuitry having an input coupled to the AUX PFD circuitry and an output, filter circuitry having a first input coupled to the output of the transconductor circuitry, a second input coupled to the output of the RCP circuitry, and an output, and voltage controlled oscillator (VCO) circuitry having an input coupled to the output of the filter circuitry and having an output.

A third example apparatus comprises extender circuitry including: a current source having a first terminal and a second terminal, a first transistor having a source terminal coupled to the current source, a control terminal coupled to the original reference clock signal, and a drain terminal, a first switch having a first terminal coupled to the drain terminal of the first transistor, a control terminal, and a second terminal, a first capacitor having a first terminal coupled to the second terminal of the first switch and a second terminal, a second transistor having a source terminal coupled to the drain terminal of the first transistor, a control terminal, and a drain terminal, a third transistor having a source terminal coupled to the current source, a control terminal coupled to the original reference clock signal, and a drain terminal, a second switch having a first terminal coupled to the drain terminal of the first transistor, a control terminal, and a second terminal, a second capacitor having a first terminal coupled to the second terminal of the second switch and a second terminal, a fourth transistor having a source terminal coupled to the drain terminal of the third transistor, a control terminal, and a drain, a resistor having a first terminal coupled to the drain terminal of the first transistor and a second terminal, a third switch having a first terminal coupled to the drain terminal of the first transistor, a control terminal, and a second terminal coupled to the drain terminal of the third transistor, a third capacitor having a first terminal coupled to the drain terminal of the second transistor and a second terminal coupled to the drain terminal of the first transistor, and common mode feedback (CMFB) circuitry having a first terminal coupled to the drain terminal of the first transistor, a second terminal coupled to the drain terminal of the third transistor, and a third terminal coupled to the drain terminals of both the third and fourth transistors, and switch capacitor filter circuitry including: a first capacitor having a first terminal coupled to the second terminal of the first switch and a second terminal, a second switch having a first terminal coupled to the second terminal of the first capacitor, a control terminal and a second terminal, a third switch having a first terminal coupled to the second terminal of the first capacitor, a control terminal, and a second terminal, a fourth switch having a first terminal coupled to the second terminal of the first switch, a control terminal and a second terminal coupled to an output of transconductor circuitry, a second capacitor having a first terminal coupled to the second terminal of the first switch and a second terminal, and, a third capacitor having a first terminal coupled to the second terminal of the fourth switch and a second terminal.

### BRIEF DESCRIPTION OF THE DRAWINGS

FIG. 1 is a block diagram of a first example implementation of phase locked loop (PLL) circuitry.

FIG. 2 is a graph of an example performance of the PLL circuitry of FIG. 1.

FIG. 3 is a circuit diagram of a first example implementation of the sampler phase detection (PD) circuitry of FIG. 1.

FIG. 4 is a circuit diagram of a second example implementation of the extender circuitry of FIG. 3.

FIG. 5 is a circuit diagram of a third example implementation of the extender circuitry of FIG. 3.

FIG. 6 is a graph of an example performance of the circuitry of FIG. 5.

FIG. 7 is a block diagram of an example transfer function of the PLL circuitry of FIG. 1.

FIG. 8 is a circuit diagram of a second example implementation of the switch capacitor filter (SCF) circuitry of FIG. 3.

FIG. 9 is a block diagram of a second example implementation of PLL circuitry.

FIG. 10A is a flowchart representative of example machine-readable instructions or example operations that may be at least one of executed, instantiated, or performed using an example programmable circuitry implementation of the PLL circuitry of FIG. 9.

FIG. 10B is a flowchart representative of example machine-readable instructions or example operations that may be at least one of executed, instantiated, or performed to implement the auxiliary path of FIG. 10A.

FIGS. 11A, 11B, and 11C are graphs of an example performance of the PLL circuitry of FIG. 9.

FIG. 12 is a block diagram of an example vehicle including an example advanced driver-assistance (ADAS) system and an example in-vehicle infotainment (IVI) system.

FIG. 13 is a block diagram of an example of the ADAS system of FIG. 12 including example deserializer circuitry and example serializer circuitry.

FIG. 14 is a block diagram of an example IVI system of FIG. 12 including example serializer circuitry, and example deserializer circuitry.

FIG. 15 is a block diagram including examples of the serializer and deserializer circuitry of FIGS. 13 and 14, which may be referred to as a serial-deserializer (SerDes) system, the serializer and deserializer circuitry further including retimer circuitry.

The drawings are not necessarily to scale. Generally, the same reference numbers in the drawing(s) and this description refer to the same or similar (functionally and structurally) features and parts. Although the drawings show regions with clean lines and boundaries, some or all of these lines and boundaries may be idealized. In reality, the boundaries or lines may be unobservable, blended or irregular.

### DETAILED DESCRIPTION

One architecture used in industry to generate clock signals is Phase Locked Loop (PLL) circuitry. In general, PLL circuitry refers to a control system that generates a signal whose phase is the same (for example, locked) as the phase of a received signal and whose frequency is different. Some PLL circuits can only generate signals whose frequency is an integer multiple of the reference frequency of the received signal. Such an architecture is referred to as integer-based PLL circuitry. Other PLL circuits can also generate signals whose frequency are a fractional portion of the reference frequency of the received signal. Such an architecture is referred to as fractional PLL circuitry.

As industry continues to advance electronic design, the performance requirements of clock generation circuitry also includes. For example, designer or manufacturer of a flat panel display (FPD) system may require fractional PLL circuitry to generate multiple high frequency clock signals (for example, between 10 to 15 GHZ) using a low frequency clock signal (for example, approximately 25 MHz) that is received from a system level clock source (for example, a crystal oscillator). In this example, the designer or manufacturer provides one or more of the high frequency clock signals to deserializer or serializer circuitry within the FPD system. Accordingly, the designer or manufacturer requires the high frequency clock signals jitter for less than 200 femtoseconds after a change in voltage.

Generally, known fractional PLL architectures form a negative feedback loop that includes Phase Frequency Detector (PFD) circuitry and Charge Pump (CP) circuitry. The PFD circuitry in such an architecture generates two signals whose difference in phase is based on the amount of error between a reference clock signal and a feedback clock signal. The CP circuitry then uses the difference in phase to increase or decrease the current provided to a Low Pass Filter (LPF) within the feedback loop, thereby changing the phase of a Voltage Controlled Oscillator (VCO) within the feedback loop and changing the phase of the generated signal.

CP circuits generally generate large amounts of electrical noise that negatively affects performance requirements such as jitter. Some designers or manufacturers suppress CP noise by increasing the amount of current that flows through the CP circuitry. However, increasing the current also increases the power consumed by the CP circuitry and the area required on an integrated circuit to implement the CP circuitry. In the foregoing FPD context, known fractional PLL architectures cannot meet the jitter requirements while also meeting the area requirements and power consumption requirements of the system's clock generation circuitry. More generally, because known fractional PLL architectures present a trade-off between noise, power consumption, and area, known fractional PLL architectures are unable to support use cases with strict performance requirements.

Methods, apparatus, and systems described herein implement a new fractional PLL architecture that can generate multiple high frequency clock signals while simultaneously supporting strict noise and area requirements. Example PLL circuitry includes example Sampler Phase Detector (PD) circuitry that expresses the amount of error between a reference clock signal and a feedback clock signal as a difference in voltage rather than a difference in phase. As a result, the example PLL circuitry does not implement known CP architectures as described above. Rather, example transconductor circuitry converts the difference in voltage from the Sampler PD circuitry to an amount of current and provides the current to example LPF circuitry.

To express the error in voltage, the sampler PD circuitry includes example extender circuitry to ensure the reference signal has a rise time that is sufficiently slow and sufficiently linear to support variations in when the feedback signal changes state. The sampler PD circuitry also includes switch capacitor filter circuitry to sample and hold the value provided by the extender circuitry. Examples described herein provide three different implementations of the extender circuitry and two different implementations of the SCF circuitry. The various implementations vary in design, performance, and cost so that example manufacturers and designers can select an implementation that best meets a particular use case.

The example Sampler PD circuitry introduces slewing regions in the reference clock signal where the generated clock signal slews and introduces error if sample during a slewing region. Accordingly, in some examples, the PLL circuitry described herein includes reduced charge pump (RCP) circuitry on a path that is auxiliary to the sampler PD circuitry. The RCP circuitry consumes less power and area than known CP architectures used in other PLL circuits. The simplified CP circuitry adds current into the LPF based on the polarity of the error. The amount of time required for reference clock signal to exit the slewing region is responsive to the extra current, thereby making the feedback loop as a whole settle quicker.

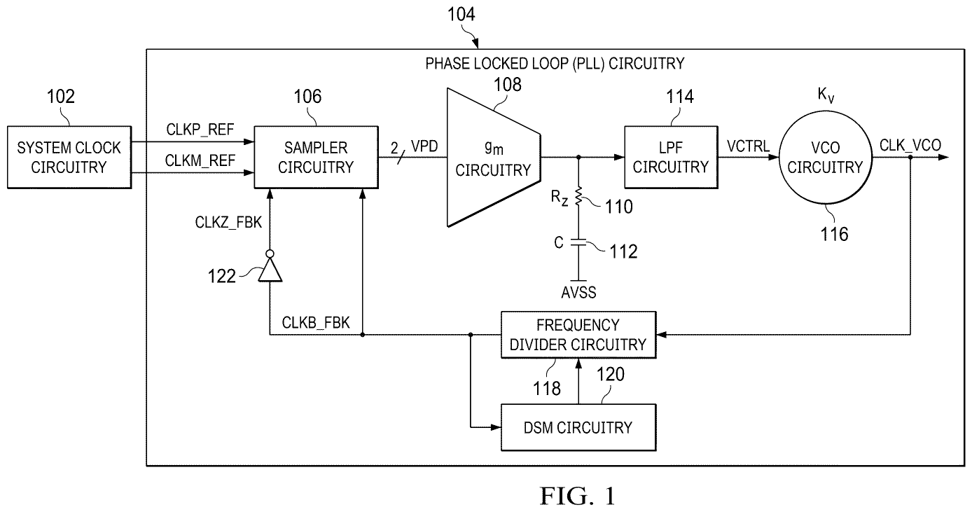

FIG. 1 is a block diagram of an example implementation of Phase Locked Loop (PLL) circuitry as described herein. FIG. 1 includes example system clock circuitry 102 and example PLL circuitry 104. The PLL circuitry 104 includes example sampler phase detector (PD) circuitry 106, example transconductor (gₘ) circuitry 108, an example resistor 110, an example capacitor 112, example LPF (low pass filter) circuitry 114, example Voltage Controlled Oscillator (VCO) circuitry 116, example frequency divider circuitry 118, example delta sigma modulation (DSM) circuitry 120, and example inverter circuitry 122.

The system clock circuitry 102 generates a differential reference clock signal. As used herein, the positive portion of the differential reference clock signal is referred to as CLK_P_REF and the portion of the differential reference clock signal is referred to as CLK_M_REF (where ‘M’ stands for minus). The two portions of the reference clock signal are collectively referred to as CLK_REF. In the FPD example described above, the system clock circuitry 102 is a crystal oscillator and the CLK_REF signal has a frequency of approximately 25 MHz. In other examples, the system clock circuitry 102 has a different source and the CLK_REF signal has a different frequency. In other examples, the CLK_REF signal is single ended rather than differential.

Within the PLL circuitry 104, the sampler PD circuitry 106 has a first terminal to receive the CLKP_REF signal and a second terminal to receive the CLKM_REF signal from the system clock circuitry 102. The sampler PD circuitry 106 also has a third terminal to receive a feedback clock signal and a fourth terminal to receive the inverse of the feedback clock signal. As used herein, the original feedback signal (as produced by the frequency divider circuitry 118) is referred to as CLKB_FBK and the inverse of the feedback clock signal (as produced by the inverter circuitry 122) is referred to as CLKZ_FBK. The CLKB_FBK signal is ideally equal in phase to the CLK_REF signal. Accordingly, any difference in phase between the CLK_REF signal and the CLKB_FBK signal is considered error.

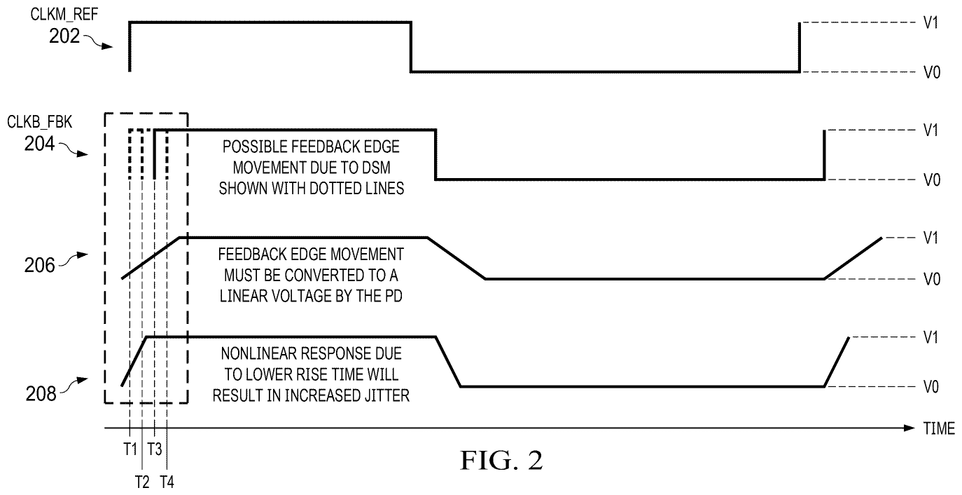

The sampler PD circuitry 106 quantifies the error between the CLK_REF signal and the CLKB_FBK signals as a voltage. To do so, the sampler PD circuitry 106 samples the CLK_REF signal on a rising edge (for example, when the CLK_REF signal is transitioning from a voltage that represents a logical ‘0’ to a voltage that represents a logical ‘1’). The sampler PD circuitry 106 samples two voltages at different times in response to identifying a rising edge in the CLKB_FBK signal. As used herein, the two sample voltages are referred to as VPD_P and VPD_M respectively and as VPD collectively. The sampler PD circuitry 106 is described further in connection with FIGS. 2-8.

The gₘ circuitry 108 has two inputs that are coupled to two corresponding outputs of the sampler PD circuitry 106. Accordingly, the gₘ circuitry 108 receives two signals whose differences in voltage represents the error described above. The gₘ circuitry 108 then generates a signal having an amount of current is proportional to the difference in voltage. In some examples, the gₘ circuitry 108 is referred to as voltage to current conversion or as gₘ cell circuitry. The gₘ circuitry 108 may be implemented using any suitable circuit architecture.

The resistor 110 has a first terminal coupled to the output of the gₘ circuitry 108 and a second terminal. The capacitor 112 has a first terminal coupled to the second terminal of the resistor 110 and a second terminal configured to receive a supply voltage (AVSS). The examples of FIGS. 1-9 are described with reference to AVSS instead of ground. In other examples, the PLL circuitry 104 is implemented with ground wherever AVSS is shown throughout the FIGS. 1-9.

The low pass filter circuitry 114 has an input coupled to both the output of the gₘ circuitry 108 and the first terminal of the resistor 110. The LPF circuitry 114 may be implemented using any suitable circuit architecture. The resistor 110, the capacitor 112, and the LPF circuitry 114 collectively edit the signal from the gₘ circuitry 108 to remove high frequency components in the signal that are responsive to noise. The LPF circuitry 114 also provides a control voltage, referred to herein as VCTRL, at its output.

The VCO circuitry 116 has an input coupled to the output of the LPF circuitry 114 and output. The VCO circuitry 116 generates a clock signal at its output whose frequency is proportional to VCTRL. As used herein, a clock signal generated by the VCO circuitry 116 is referred to as the CLK_VCO signal. The CLK_VCO signal may be set to any frequency and be used for any purpose. In the FPD context described above, the CLK_VCO signal varies between 10 to 15 GHz and is used for deserializer or serializer operations.

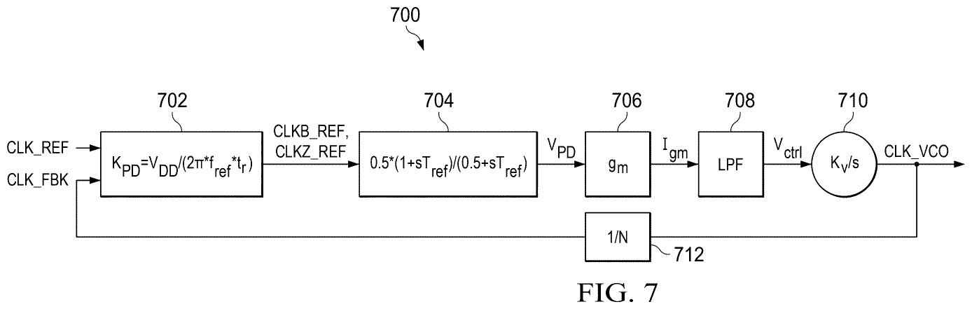

In some examples, the signal flow from the sampler PD circuitry 106 to the gₘ circuitry 108, the LPF circuitry 114, and the VCO circuitry 116 may be referred to as a forward path. In such examples, the signal flow from the VCO circuitry, through the frequency divider circuitry 118, and back to the sampler PD circuitry 106 is referred to as the feedback path of the PLL circuitry 104. The frequency divider circuitry 118 has an input coupled to the output of the VCO circuitry 116 and an output coupled to the sampler PD circuitry 106. The frequency divider circuitry 118 generates a signal whose frequency is a fractional portion of the VCO circuitry 116. The frequency divider circuitry 118 therefore reduces the frequency of the CLK_VCO signal such that the output of the frequency divider circuitry 118 (referred to herein as the CLKB_FBK signal) and the CLK_REF signal have approximately equal frequencies and can be compared by the sampler PD circuitry 106. The gain of the PLL circuitry 104 is described further in connection with FIG. 7.

The DSM circuitry 120 has an input coupled to the output of the frequency divider circuitry 118 and an output coupled to the input of the frequency divider circuitry 118. The DSM circuitry 120 is a type of analog-to-digital converter (ADC) that increases the frequency of a signal received at its input by performing oversampling. Thus, the DSM circuitry 120 and the frequency divider circuitry 118 form a feedback loop themselves to ensure the frequency of the CLK_FBK signal matches that of the CLK_REF signals.

In this example, the DSM circuitry 120 is implemented using digital hardware logic on the same chip as the other components of the PLL circuitry 104. More generally, the DSM circuitry 120 of FIG. 1 may be instantiated (for example, creating an instance of, bring into being for any length of time, materialize, implement, etc.) by programmable circuitry such as a Central Processor Unit (CPU) executing first instructions. Also or alternatively, the DSM circuitry 120 may be instantiated (for example, creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 2 may, thus, be instantiated at the same or different times. Some or all of the circuitry of FIG. 2 may be instantiated, for example, in one or more threads executing concurrently on hardware or in series on hardware. Moreover, in some examples, some or all of the circuitry of FIG. 2 may be implemented by microprocessor circuitry executing instructions or FPGA circuitry performing operations to implement one or more virtual machines or containers.

The output of the frequency divider circuitry 118 is also coupled to the inverter circuitry 122. The inverter circuitry 122 produces the CLKZ_FBK signal, which is an inverted version of the CLKB_FBK signal produced by the frequency divider circuitry 118. Accordingly, the voltage of the CLKZ_FBK signal represents a logical ‘0’ whenever the voltage of the CLKB_FBK signal represents a logical ‘1’ and vice versa.

FIG. 2 is a graph of an example performance of the PLL circuitry of FIG. 1. The graph of FIG. 2 includes example signals 202, 204, 206, and 208. The signals 202-208 share a common x axis and are therefore vertically aligned in time. The time axis includes timestamps T1, T2, T3, and T4. The signals 202-208 have their own y axes that each span from V0 to V1. As used above and herein, V0 refers to a voltage representing a logical ‘0’ (for example, a low supply voltage) and V1 refers to a voltage representing a logical 1 (for example, a high supply voltage).

The signal 202 is an example snippet of the CLKM_REF signal provided by the system clock circuitry 102 of FIG. 1. The snippet of the signal 202 shown in FIG. 2 spans approximately one wavelength. The wavelength begins at T1 when the signal 202 transitions from a V0 to V1.

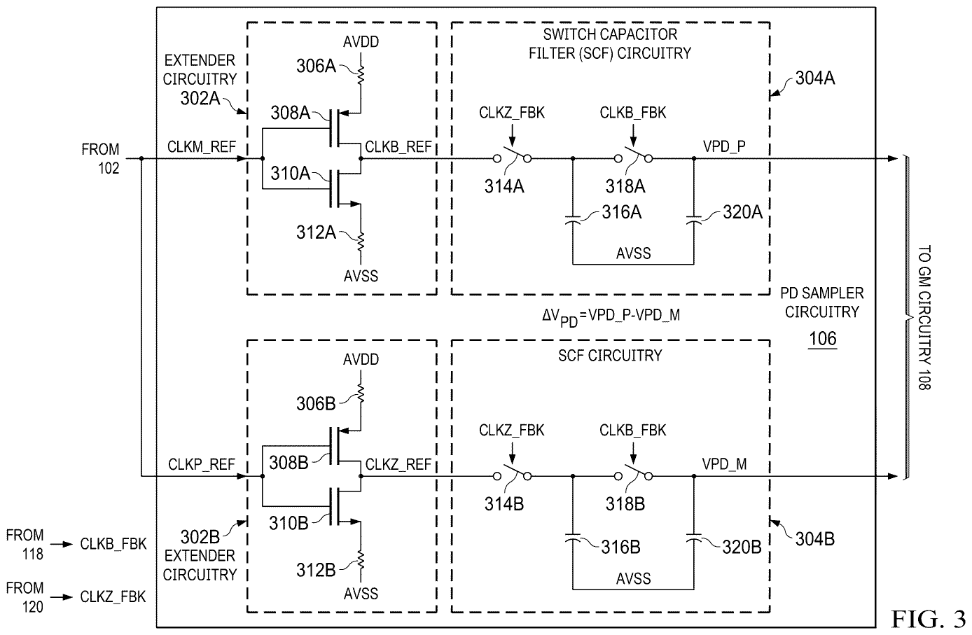

The signal 204 is an example snippet of the CLKB_FBK signal provided by the frequency divider circuitry 118. Because the feedback path of the PLL circuitry 104 counteracts the gain of the feedforward path, the CLKB_FBK signal and CLKM_REF signal are ideally equal in both phase and frequency. However, in the example of FIG. 2, the transition from the logical ‘0’ to a logical ‘1’ is represented by a solid line and occurs in the signal 204 at T3. Accordingly, the signal 202 and 204 are out of phase. More generally, because the amount of error in the PLL circuitry can vary over time, the rising edges of the CLKB_FBK signal during other wavelengths may occur at T1, T2, T4, or at any other timestamp near the corresponding rising edges of the CLKM_REF signal. The potential variance of the rising edge of the CLK_FBK signals is represented in the example of FIG. 3 as dashed lines. In some examples, the foregoing potential variance is referred to as feedback edge movement.

The sampler PD circuitry 106 quantifies the phase difference between the signals 202 and 204 as a voltage and as described above. To do so, the sampler PD circuitry 106 generates an internal signal that extends the rise time of the CLK_REF signals. For example, in FIG. 2, the sampler PD circuitry 106 generates the signal 206 based on the signal 202. Like the original signal 202, the signal 206 also transitions from V0 to V1. However, the signal 206 begins to transition between logical states before T1 and ends the transition after T4. Thus, any of the potential variance from the signal 202 occurs during the rise time of the signal 206. As used herein, the period in which a signal transitions from V0 to V1 is referred to as a rise time.

The sampler PD circuitry 106 samples the adjusted version of the CLK_REF signal with an extended rise time at the rising edge of the CLK_FBK. Because the adjusted clock signal changes linearly from V0 to V1, the voltage sampled and generated by the sampler PD circuitry 106 changes based on the amount of phase error. For example, in FIG. 2, the rising edge of the signal 204 occurs at T3 and the value of VPD_M is therefore approximately halfway between V0 and V1. Had the rising edge of the signal 204 instead occurred at T2, the sampler PD circuitry 106 would have sampled a smaller voltage. Moreover, the difference in voltage between the two examples is proportional to the difference in time between T2 and T3. Thus, the sampler PD circuitry 106 uses the signal 206 to convert the feedback edge movement of the signal 204 to a voltage.

The signal 208 is an example of an adjusted version of the signal 202. The signal 208 is shown in FIG. 2 for explanatory purposes but is not generated by the sampler circuitry 106. The example of FIG. 2 shows the signal 208 has a rise time that is extended (for example, longer) when than the signal 202 but shorter than the signal 206. In particular, the rise time of the signal 208 is sufficiently short that a) a rising edge of the signal 204 at T3, and b) a rising edge of the signal 204 at T4, would both correspond to the same voltage (V1) when the signal 208 is sampled. If the sampler PD circuitry 106 were to attempt to use the signal 208 to represent phase error as a voltage, the circuit would exhibit a nonlinear response due to the comparatively small rise time that results in increased jitter and decreased performance of the PLL circuitry 104. Accordingly, designers and manufacturers that implement the example sampler PD circuitry 106 seek to avoid generating the signal 208 and instead generate the signal 206 by a) extending the rise time of the CLK_REF signals to be longer than the window for possible feedback edge movement. Designers and manufactures also seek to ensure the rise time of the adjusted CLK_REF signal is as linear as possible so that sampling the adjusted CLK_REF signal accurately quantizes the phase error.

FIG. 3 is a circuit diagram of a first example implementation of the sampler PD circuitry 106 of FIG. 1. FIG. 3 shows the sampler PD circuitry 106 includes example extender circuitry 302A and 302B (collectively referred to as extender circuitry 302) and example switch capacitor filter (SCF) circuitry 304A and 304B (collectively referred to as SCF circuitry 304). FIG. 3 also includes the CLK_REF signals, the CLK_FBK signals, and the VPD signals as described above in FIG. 1, an example CLKB_REF signal, and an example CLKZ_REF signal. As used above and herein, the CLKB_REF refers to an adjusted version of the CLKM_REF signal and CLKZ_REF signal refers to an adjusted version of the version of the CLKP_REF signal as described in FIG. 2.

Within the extender circuitry 302A shown in the example of FIG. 3, the resistor 306A has a first terminal to receive a first supply voltage (AVDD) and a second terminal. The transistor 308A has a source terminal coupled to the second terminal of the resistor 306A, a control terminal to receive the CLKM_REF signal, and a drain terminal coupled to the SCF circuitry 304A. The transistor 310A has a source terminal coupled to the SCF circuitry 304A and the drain of the transistor 308A, a control terminal to receive the CLKM_REF signal, and a drain terminal. The resistor 312A has a first terminal coupled to the drain terminal of the transistor 310A and a second terminal to receive a second supply voltage (AVSS). The voltage at the drain terminal of the transistor 308A and the source terminal of the transistor 310A is the CLKB_REF signal.

The extender circuitry 302B is a mirrored version of the extender circuitry 302A. Accordingly, the resistor 306B, the transistor 308B, the transistor 310B, and the resistor 312B connect to one another and function in the same way that the resistor 306A, the transistor 308A, the transistor 310A, and the resistor 312A. However, while the extender circuitry 302A receives the CLKM_REF signal at its input and generates the CLKB_REF signal at its output, the extender circuitry 302B receives the CLKZP_REF signal at its input and generates the CLKP_REF signal at its output. Thus, in the example of FIG. 3, the sampler PD circuitry 106 implements two instances of the foregoing extender circuitry to support differential signaling. In other examples, the sampler PD circuitry 106 implements only one instance of the extender circuitry of FIG. 3 and supports single-ended signaling.

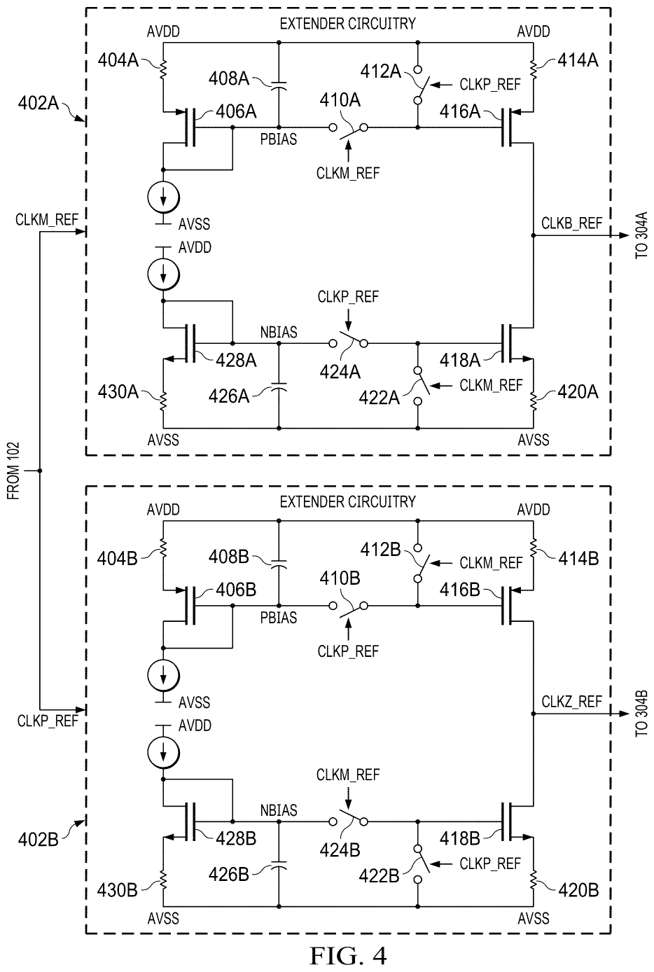

In the example of FIG. 3, the extender circuitry 302A and 302B implement an inverter architecture to slow down (for example extend) the rise and fall times of the CLKM_REF signals and CLKP_REF signals, respectively. Notably, in other examples described herein, the sampler PD circuitry 106 implements the extender circuitry using a different circuit architecture. Other example implementations of the extender circuitry are described further in connection with FIGS. 4-6.

Within the SCF circuitry 304A, the switch 314A has a first terminal coupled to the extender circuitry, a control terminal to receive the CLKZ_FBK signal, and a second terminal. As used above and herein, a control terminal of the switch refers to the terminal whose voltage determines whether the switch is in the open or closed state. The capacitor 316A has a first terminal coupled to the second terminal of the switch 314A and a second terminal to receive AVSS. The switch 318A has a first terminal coupled to the second terminal of the switch 314A, a control terminal to receive the CLKB_FBK signal, and a second terminal coupled to the gₘ circuitry 108. The capacitor 320A has a first terminal coupled to the second terminal of the switch 318A and a second terminal to receive AVSS. The voltage at the second terminal of the switch 318A and the first terminal of the capacitor 320A is VPD_P as described above.

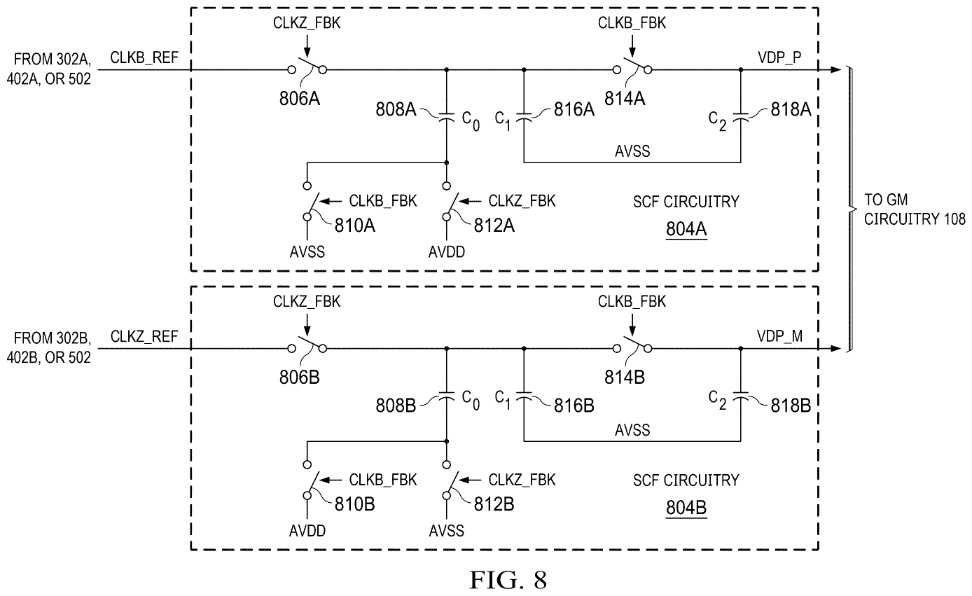

The SCF circuitry 304A and 304B are two instances of the same architecture described above. Accordingly, the switch 314B, the capacitor 316B, the switch 318B, and the capacitor 320B connect to one another and operate in the same manner as the switch 314A, the capacitor 316A, the switch 318A, and the capacitor 320A. For example, when the CLKZ_FBK signal is at V1, the switches 314A and 314B are both closed so the voltages of the CLKB_REF signals and the CLKZ_REF signals charge the capacitors 316A and 316B, respectively. CLKB_FBK is at V0 whenever CLKZ_FBK is at V1, so the switches 318A and 318B remain open during such time. Once the foregoing clock cycle ends, CLKZ_FBK switches from V1 to V0 and CLKB_FBK switches from V0 to V1. At such time, the voltage stored in the capacitor 316A is redistributed to the capacitor 320A and the voltage stored in the capacitor 316B is stored in the capacitor 320B. Thus, the SCF circuitry 304A acts as a track and hold node that samples an elongated square wave (CLKB_REF and CLKZ_REF) and performs first order filtering on the signal so that the value of VPD does not swing from V0 to V1 with the reference clock. Accordingly, the input of the gₘ circuitry 108 is only required to support the smaller swing of VPD and does not have to swing rail to rail. In other examples described herein, the sampler PD circuitry 106 implements the SCF circuitry using a different circuit architecture. Another example implementations of the SCF circuitry is described further in connection with FIG. 8.

FIG. 4 is a circuit diagram of a second example implementation of the extender circuitry of FIG. 3. Accordingly, the extender circuitry 402A and 402B of FIG. 4 receive the same signals at their input (CLKM_REF and CLKP_REF from the system clock circuitry 102 of FIG. 1) and generate the same signals at their output (adjusted versions of the reference clock signal with extended rise times that are labeled CLKB_REF and CLKZ_REF, respectively) as the extender circuitry 302A and 302B of FIG. 3. Thus, in some examples, a designer or manufacturer implements the sampler PD circuitry 106 using the extender circuitry 402A instead of the extender circuitry 302A and using the extender circuitry 402B instead of the extender circuitry 302B.

Within the extender circuitry 402A, the resistor 404A has a first terminal to receive a first supply voltage (AVDD) and a second terminal. The transistor 406A has a source terminal coupled to the second terminal of the resistor 404A, a control terminal, and a drain terminal. The drain terminal of the transistor 406A is both coupled to the control terminal of the transistor 406A and to receive a second supply voltage (AVSS). The capacitor 408A has a first terminal to receive the first supply voltage and a second terminal coupled to the control terminal of the transistor 406A. The switch 410A has a first terminal coupled to the control terminal of the transistor 406A, a control terminal to receive the CLKM_REF signal, and a second terminal. The switch 412A has a first terminal to receive AVDD, a control terminal to receive the CLKP_REF signal, and a second terminal coupled to the second terminal of the switch 410A. The resistor 414A has a first terminal to receive AVDD and a second terminal. The transistor 416A has a source terminal coupled to the second terminal of the resistor 414A, a control terminal that is coupled to both the second terminal of the switch 410A and the second terminal of the switch 412A, and a drain terminal coupled to the SCF circuitry 304A.

Still within the extender circuitry 402A, the transistor 418A has a source terminal coupled to both the SCF circuitry 304A and the drain terminal of the transistor 416A. The transistor 418A also has a control terminal, and a drain terminal. The resistor 420A has a first terminal coupled to the drain terminal of the transistor 418A and a second terminal to receive AVSS. The switch 422A has a first terminal coupled to the control terminal of the transistor 418A, a control terminal to receive the CLKM_REF signal, and a second terminal to receive AVSS. The switch 424A has a first terminal coupled to the control terminal of the transistor 418A, a control terminal to receive the CLKP_REF signal 424A, and a second terminal. The capacitor 426A has a first terminal coupled to the second terminal of the switch 424A and a second terminal to receive AVSS. The transistor 428A has a source terminal to receive AVDD, a control terminal coupled to both the source terminal of the transistor 428A and to the second terminal of the switch 424A, and a drain terminal. The fourth resistor 430A has a first terminal coupled to the drain terminal of the transistor 428A and a second terminal to receive AVSS.

The extender circuitry 402B is a mirrored version of the extender circuitry 402A. Accordingly, the components 404B-430B connect to one another in the same manner that the components 404A-430A connect to one another as described above. However, the two circuitry instances are mirrored in the sense that the switches 412A and 424A receive the CLKP_REF signal in the extender circuitry 402A while the switches 412B and 424B receive the CLKM_REF signal in the extender circuitry 402B. Similarly, the switches 410A and 422A receive the CLKM_REF signal in the extender circuitry 402A while the switches 410B and 422B receive the CLKP_REF signal in the extender circuitry 402B. Thus, in the example of FIG. 4, the sampler PD circuitry 106 implements two instances of the foregoing extender circuitry to support differential signaling. In other examples, the sampler PD circuitry 106 implements only one instance of the extender circuitry shown in FIG. 4 and supports single-ended signaling.

Within a given instance of the extender circuitry 402A, the resistor 414A, the transistor 416A and 418A, and the resistor 420A forms the same inverter structure that is present within the extender circuitry 302A of FIG. 3. However, while the behavior of the transistors 308A and 310A are controlled by the CLKM_REF signal in FIG. 3, the behavior of the transistors 416A and 418A are controlled by bias voltages labelled in FIG. 4 as PBIAS and NBIAS, respectively. The value of PBIAS is determined by the resistor 404A, the transistor 406A, and the capacitor 408A, which collectively operate like a current source as shown in FIG. 4. Similarly, the value of NBIAS is determined by the operation of the resistor 404A, the transistor 406A, and the capacitor 408A.

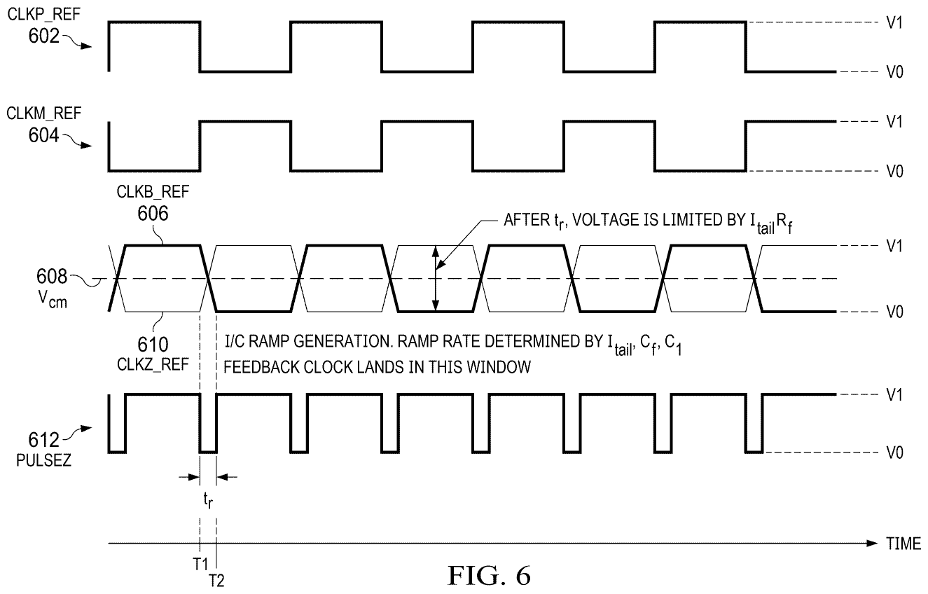

The transistors 416A and 418A of FIG. 4 have a larger headroom voltage than the transistors 308A and 310A of FIG. 3 because the transistors 416A and 418A receive bias voltages at their control terminals instead of the CLKM_REF signal. The increased headroom allows the extender circuitry 304A to generate a transition from V0 to V1 in the CLKB_REF signal that remains linear for a comparatively longer portion of the rise time. In contrast, the transition from V0 to V1 produced by the extender circuitry 402A is linear for a comparatively shorter portion of the rise time because the headroom voltage of the transistor 308A decreases throughout the transition. The CLKB_REF signal becomes nonlinear and asymptotically approach V1 once the transistor 308A becomes saturated. In turn, the rate at which the transistor 308A saturates is responsive to the loss of headroom voltage. Accordingly, the extender circuitry 402 of FIG. 4 supports a greater amount of possible feedback edge movement (for example, performs better) than the extender circuitry 302 of FIG. 3 because the extender circuitry 402 produces a rise time with higher linearity than the extender circuitry 302. However, the extender circuitry 402 is more expensive and requires a larger amount of area to implement than the extender circuitry 302 because the extender circuitry 402 uses a greater number of components than the extender circuitry 302. Additional comparison of the foregoing circuit architectures is described further in connection with FIG. 6.

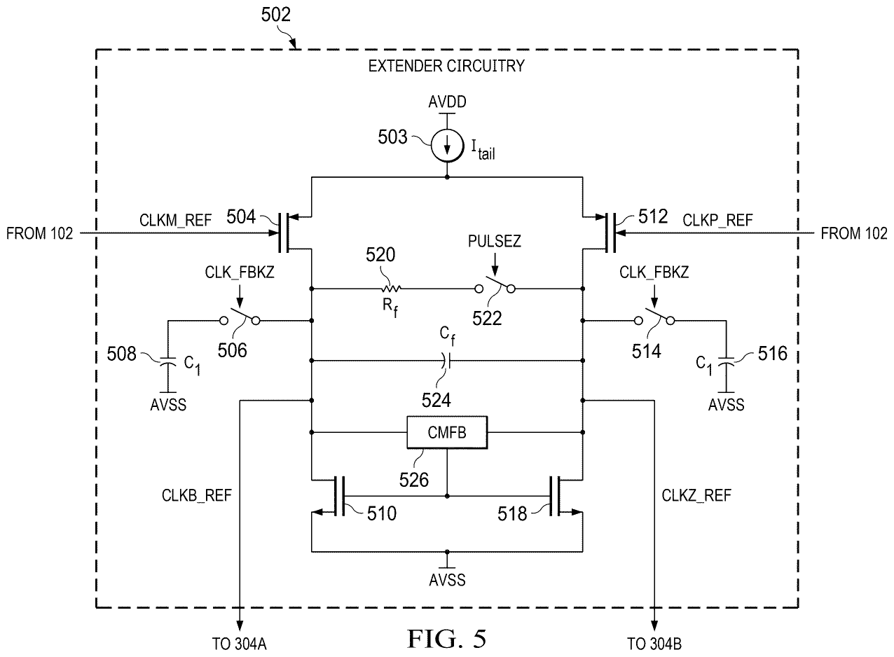

FIG. 5 is a circuit diagram of a third example implementation of the extender circuitry of FIG. 3. Accordingly, the extender circuitry 502 of FIG. 5 receive the same signals at its input (CLKM_REF and CLKP_REF from the system clock circuitry 102 of FIG. 1) and generates the same signals at its output (adjusted versions of the reference clock signal with extended rise times that are labeled CLKB_REF and CLKZ_REF, respectively) as the extender circuitry 302 and the extender circuitry 402 of FIGS. 3 and 4. Thus, in some examples, a designer or manufacturer implements the sampler PD circuitry 106 using the extender circuitry 502 instead of the extender circuitry 302 or 402.

Within the extender circuitry 502, the current source 503 has a first terminal coupled to receive a first supply voltage (AVDD) and a second terminal. The transistor 504 has a source terminal coupled to the current source 503, a control terminal coupled to the CLKM_REF signal, and a drain terminal. The switch 506 has a first terminal coupled to the drain terminal of the transistor 504, a control terminal to receive the CLK_ZFBK signal, and a second terminal. The capacitor 508 has a first terminal coupled to the second terminal of the switch 506 and a second terminal coupled to a second supply voltage (AVSS). The transistor 510 has a source terminal coupled to the drain terminal of the transistor 504, a control terminal, and a drain terminal coupled to AVSS.

Still within the extender circuitry 502, the transistor 512 has a source terminal coupled to the second terminal of the current source 503, a control terminal coupled to the CLKP_REF signal, and a drain terminal. The switch 514 has a first terminal coupled to the drain terminal of the transistor 512, a control terminal to receive the CLKZ_FBK signal, and a second terminal. The capacitor 516 has a first terminal coupled to the second terminal of the switch 514 and a second terminal coupled to AVSS. The transistor 518 has a source terminal coupled to the drain terminal of the transistor 512, a control terminal, and a drain terminal coupled to AVSS. The capacitors 516 and 508 have the same capacitance value that is labeled in the example of FIG. 5 as C₁.

Still within the extender circuitry 502, the resistor 520 has a first terminal coupled to the drain terminal of the transistor 504 and a second terminal. The switch 522 has a first terminal coupled to the second terminal of the resistor 520, a control terminal to receive a PULSEZ signal, and a second terminal coupled to the drain terminal of the transistor 512. The capacitor 524 has a first terminal coupled to the drain terminal of the transistor 512 and a second terminal coupled to the drain terminal of the transistor 504.

The common mode feedback (CMFB) circuitry 526 has a first terminal coupled to the drain terminal of the transistor 504 and a second terminal coupled to the drain terminal of the transistor 512. The CMFB circuitry also has a third terminal coupled to the drain terminals of the transistors 510 and 518. In the example of FIG. 5, the extender circuitry 502 acts as a differential amplifier. The first and second terminals CMFB circuitry 526 monitors the average voltage at the outputs of the extender circuitry 502. The CMFB circuitry 526 then generates a control voltage at its third terminal to adjust the bias of the extender circuitry 502, effectively canceling out any common-mode signals that might otherwise affect the desired differential signal (for example, the CLKB_REF and the CLKZ_REF signals). The CMFB circuitry 526 may be implemented using any suitable technique.

In the examples of FIGS. 3-5, the transistors 308A, 308B, 406A, 416A, 406B, 416B, 504, and 512 are n-channel metal-oxide semiconductor field-effect transistors (MOSFETs). Alternatively, the transistors 308A, 308B, 406A, 416A, 406B, 416B, 504, and 512 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. The transistors 308A, 308B, 406A, 416A, 406B, 416B, 504, and 512 may be depletion mode devices, drain-extended devices, enhancement mode devices, natural transistors or other type of device structure transistors. Furthermore, the transistors 308A, 308B, 406A, 416A, 406B, 504, and 512 may be implemented in/over a silicon substrate (Si), a silicon carbide substrate (SiC), a gallium nitride substrate (GaN) or a gallium arsenide substrate (GaAs).

In the examples of FIGS. 3-5, the transistors 310A, 310B, 418A, 428A, 418B, 428B, 510, and 518 are p-channel MOSFETs. Alternatively, the transistors 310A, 310B, 418A, 428A, 418B, 428B, 510, and 518 may be p-channel FETs, p-channel IGBTs, p-channel JFETs, PNP BJTs, or, with slight modifications, N-type equivalent devices. The transistors 310A, 310B, 418A, 428A, 418B, 428B, 510, and 518 may be depletion mode devices, drain-extended devices, enhancement mode devices, natural transistors or other type of device structure transistors. Furthermore, the transistors 310A, 310B, 418A, 428A, 418B, 428B, 510, and 518 may be implemented in/over a silicon substrate (Si), a silicon carbide substrate (SiC), a gallium nitride substrate (GaN) or a gallium arsenide substrate (GaAs).

FIG. 6 is a graph illustrating an example performance of the extender circuitry 502 of FIG. 5. FIG. 6 includes example signals 602, 604, 606, 608, 610. The signals 602-610 share an x axis and are therefore vertically aligned in time. The signals 602-610 also have y axes that span from V0 to V1 as described above.

The signals 602 and 604 are an example implementation of the CLKP_REF signals and CLKM_REF signals, respectively. Because the signals 602 and 604 are two components of the same differential signal, the CLKP_REF is at V0 whenever CLKM_REF is at V1 and vice versa.

The signals 606 and 610 are an example implementation of the CLKB_REF signals and the CLKZ_REF signals, respectively. FIG. 6 shows that the differential structure of the extender circuitry 502 generates the CLKB_REF and CLKZ_REF signals to swing (for example oscillate) around the common mode voltage (VCM) shown in the signal 608. To do so, current from the current source 503 is steered both towards the capacitor 508 and away from the capacitor 516 when CLKP_REF is at V1, thus increasing CLKB_REF at the same linear rate that CLKZ_REF decreases. Similarly, current from the current source 503 is steered both away from the capacitor 508 and towards the capacitor 516 when CLKP_REF is at V0, thus decreasing CLKB_REF at the same linear rate that CLKZ_REF increases.

The signal 612 is an example implementation of the PULSEZ voltage provided to the control terminal of the switch 522. The signal 612 shows that the switch 522 is used to effectively disconnect the resistor 520 from the rest of the extender circuitry 502 whenever a rise time occurs (for example, between T1 and T2) and reconnect the resistor 520 during any other state of operation. When the resistor 520 is disconnected, the capacitors 508 and 516 continue to charge or discharge based on the phase of the reference clock (for example, whether the CLKM_REF is causing the transistors 504 and 512 to steer the current from the current source towards or away from a given capacitor). Thus, by keeping the resistor 520 connected whenever the CLK_REF signals are in their steady state, the signal 612 shows that PULSEZ voltage is used to prevent the capacitors 508 and 516 from overcharging. Furthermore, because the capacitors 508 and 516 do not charge or discharge when the resistor 520 is connected, the PULSEZ voltage is also used to define the width of the rise time (shown in FIG. 6 as tᵣ). In this example, the PULSEZ voltage is generated using digital logic (including but not limited to delay cells) in the sampler circuitry 106 such that the PULSEZ signal is wide enough to allow the extender circuitry 502 to produce the desired slope of the extended rise time period.

The linear rate at which the signals 606 and 610 alternate between V0 and V1 is given by Iₜₐᵢₗ/(C₁+2C_{f}), where Iₜₐᵢₗ is the amount of current provided by the current source 503, C₁ is the value of the capacitors 508 and 516, and C_{f} is the value of the capacitor 524. More generally, the extender circuitry 502 exhibits high linearity, and therefore supports a greater amount of potential feedback edge movement as described above, than either of the extender circuitry 302 or 402 of FIGS. 3 and 4. However, the extender circuitry 502 is generally more expensive and requires more area to implement on an integrated circuit (IC) than either of the extender circuitry 302 or 402 because the extender circuitry 502 has more components (for example, the current source 503, the resistor 520, the switch 522, the CMFB circuitry 526, etc.). Furthermore, while the extender circuitry 302 and 402 can be modified to support both differential and single-ended signaling as described above, the extender circuitry 502 does not support single-ended signaling because the circuitry fundamentally relies on a differential clock signal to steer current back and forth between the capacitors 508 and 516. Accordingly, a manufacturer or designer that implements the sampler PD circuitry 106 using the examples described herein can choose one of the extender circuitry 302, 402, or 502 as shown in FIGS. 3, 4, and 5 based on which implementation best meets the performance, cost, and area requirements of their particular use case.

FIG. 7 is a block diagram of an example transfer function model of the PLL circuitry 104 of FIG. 1. The transfer function model 700 is a mathematical model used to quantify the gain (represented in FIG. 7 by the symbol ‘K’) that each component in the PLL circuitry 104 contributes to the generation of the CLK_VCO signal produced at the output of the VCO circuitry 116. The transfer function model 700 includes example transfer functions 702, 704, 706, 708, 710, and 712.

The transfer function 702 quantifies K_{PD}, the gain received when the switches 314A and 314B sample the CLKB_REF and CLKZ_REF during their rise times. The transfer function is given by equation (1):

$${K}_{PD} = AVDD / ( 2 π {f}_{re} {t}_{r} ) \qquad ( 1 )$$

In equation (1), f_{ref} represents the frequency of the CLK_REF signals and tᵣ represents the rise time of the CLKB_REF and CLKZ_REF signals produced by the extender circuitry.

In the example of FIG. 7, the transfer function 704 quantifies the gain of the SCF circuitry 304A presuming the values of the capacitors 316A and 320A are equal. In such examples, the gain can be modeled in the complex valued frequency-domain for a discrete-time signal (for example, the z-domain), using equation (2):

$${K}_{704} = \frac{0.5}{1 - 0.5 {z}^{- 1}} \qquad ( 2 )$$

In other examples where the values of the capacitors 316A and 320A are different, the value of K₇₀₄ changes based on the ratio of C_{316A} and C_{318A}. By substituting

$$z = ( 1 + \frac{s T}{2} ) / ( 1 - \frac{s T}{2} ) ,$$

the transfer function 704 can be converted into the complex valued frequency-domain for a continuous-time signal (for example, the s-domain) as described in equation (3):

$${K}_{704} = \frac{0.5 ( 1 + s {T}_{ref} )}{0.5 + s {T}_{ref}} \qquad ( 3 )$$

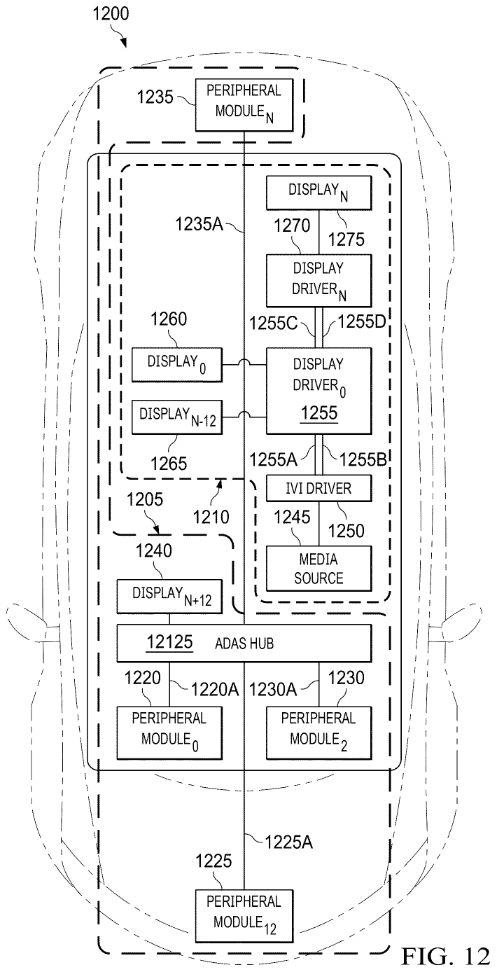

In equation (3), T_{ref} represents the rise time of the original CLK_REF signals from the system clock circuitry 102. The SCF circuitry 304 filters the CLKB_REF and CLKZ_REF signals to filter the amount of high frequency swing that the gₘ circuitry 108 sees at its input. Equation (3) shows that the SCF circuitry 304 also introduces a pole in the s-domain. Thus, the high frequency filtering offered by the SCF circuitry 304 can introduce a nonzero amount of phase error into the PLL circuitry 104. However, the phase error due to the SCF circuitry 304 is generally negligible in magnitude and acceptable within most performance requirements for high frequency clock systems. Such systems include the example FPD context mentioned above and described further in connection with FIGS. 12-15.

When the CLK_REF and CLK_FBK signals (for example, the signals at the input to the sampler PD circuitry 106) have a relatively small phase error at the input, the gain described in the transfer function 704 becomes negligible and the gain of the LPF circuitry 114 (expressed in FIG. 7 as the transfer function 708) becomes dominated by the value of the resistor 110. Thus, the feedforward gain of the PLL circuitry 104 with relatively small phase error at its input is given by equation (4):

$${K}_{FF \_ 106} = ( \frac{AVDD}{2 π {f}_{re} {t}_{r}} ) ( {g}_{m} ) ( {R}_{110} ) ( \frac{{K}_{v}}{s} ) \qquad ( 4 )$$

In contrast, known PLL circuitry implements a known phase detector architecture and a charge pump instead of the sampler PD circuitry 106 and gₘ circuitry 108. Presuming that a) the known PD architecture includes two D-flip flops whose reset terminals couple to the same AND gate as commonly used in industry, and b) the rest of the feed forward loop components in both the known PLL circuitry and the example PLL circuitry 104 are the same, the feedforward gain of known PLL circuitry that receives the same small phase error at its input is given by equation (5):

$${K}_{FF \_ known} = ( \frac{AVDD ( {I}_{c p} )}{2 π} ) ( {R}_{110} ) ( \frac{{K}_{v}}{s} ) \qquad ( 5 )$$

In equations (4) and (5), R₁₁₀ is the value of the resistor 110 and I_{cp} is the current produced by the charge pump. Equations (4) and (5) show that to achieve the same gain in both feed forward paths, the gain of the gₘ circuitry 108 would need to be given by equation (6):

$$( \frac{{g}_{m}}{{f}_{re} {t}_{r}} ) = {I}_{c p} \to {g}_{m} = {I}_{c p} {f}_{r e} {t}_{r} \qquad ( 6 )$$

In equation (6), AVDD=1 for clarity. The gain of the gₘ circuitry 108 can then be rewritten as shown in equation (7):

$${g}_{m} = \frac{{I}_{g m}}{( {g}_{m} / {I}_{d} )} \qquad ( 7 )$$

In equation (7), I_{gm} represents the current through the gₘ circuitry 108 and (gₘ/I_{d}) represents the efficiency of the gₘ circuitry 108 translate power into gain. In this example, (gₘ/I_{d})=5 and tᵣ=4 T_{VCO}. Furthermore, fᵣₑT_{VCO}=1/N, where N is the division ratio of feedback divider circuitry 118. Thus, the value of I_{gm} can be approximated as shown in equation (8):

$${I}_{g m} = {I}_{c p} {f}_{r e} {t}_{r} ( \frac{{g}_{m}}{{I}_{d}} ) = {I}_{c p} {f}_{r e} {T}_{VCO} ( 20 ) = {I}_{c p} ( \frac{20}{N} ) \approx \frac{{I}_{c p}}{20} \qquad ( 8 )$$

Equation (8) shows that, in this example, the power requirement of the PLL circuitry 104 described in examples herein is approximately 20× lower than the power requirement of known PLL circuitry for the same bandwidth. More generally, the PLL circuitry 104 can support a loss of gain by replacing the charge pump with the gₘ circuitry 108 because the gain of the example sampler PD circuitry 106 (which is AVDD/(2πfᵣₑtᵣ)) is greater than the gain of known PD architectures (which is AVDD/(2π)). The increased gain of the sampler PD circuitry 106 over the known PD architectures allows the noise requirement of the gₘ circuitry to be relaxed by a factor of 1/(fᵣₑtᵣ) without a loss of performance. Moreover, because the gₘ circuitry 108 consumes significantly less power and requires less area than known charge pumps (for example, the gₘ circuitry 108 requires approximately 2.5 μm² compared to approximately 12.5 μm² for the charge pump), example PLL circuitry described herein consumes less power and requires less area than known PLL architectures at the same bandwidth.

Notably, the integrated noise generated by the sampler PD circuitry 106 is given by kT/C and is therefore dominated by the value of the capacitors 316A and 318A. Thus, a manufacturer or designer of the sampler PD circuitry 106 can choose a value of the 316A and 318A to ensure the integrated noise of the sampler PD circuitry 106 is less than the noise of the gₘ circuitry 108.

In some examples, the gₘ circuitry 108 is always powered ON so that any change in the value of VPD (for example, any change in the phase error) is propagated through the rest of the feedback loop and subsequently corrected in real time. However, the noise produced by the gₘ circuitry 108 is relatively high in such examples because the circuit is always converting voltage to current, even when the CLKB_REF and CLKZ_REF signals are not in a rise time window and thus cannot be sampled. Accordingly, in other examples, the gₘ circuitry 108 may be duty cycled to periodically transition from powered ON to powered OFF, thereby eliminating the noise contribution whenever the gₘ circuitry is powered OFF. A designer or manufacturer may choose a higher gain for an implementation of the gₘ circuitry 108 that is duty cycled than an implementation that is always powered ON so that average gain of the gₘ circuitry 108 remains the same regardless of whether duty cycling is employed.

FIG. 8 is a circuit diagram of a second example implementation of the switch capacitor filter (SCF) circuitry of FIG. 3. Accordingly, the example SCF circuitry 804A and 804B of FIG. 8 receive the same signals at their input (CLKB_REF and CLKZ_REF, respectively) and produce the same signals at their output (VDP_P and VDP_M, respectively) as the SCF circuitry 304A and 304B of FIG. 3.

Within the SCF circuitry 804A, the switch 806A has a first terminal to receive the CLKB_REF signal from one of the extender circuitry 302A, 402A, or 502. The switch 806A also has a control terminal to receive the CLKZ_FBK signal, and a second terminal. The capacitor 808A has a first terminal coupled to the second terminal of the switch 806A and a second terminal. The switch 810A has a first terminal coupled to the second terminal of the capacitor 808A, a control terminal to receive the CLKB_FBK signal, and a second terminal to receive a first supply voltage (AVSS). The third switch 812A has a first terminal coupled to the second terminal of the capacitor 808A, a control terminal to receive the CLKZ_FBK signal, and a second terminal to receive a second supply voltage (AVDD). The switch 814A has a first terminal coupled to the second terminal of the switch 806A, a control terminal to receive the CLKB_FBK signal, and a second terminal coupled to the gₘ circuitry 108. Accordingly, the voltage at the second terminal of the switch 814A is VDP_P. The capacitor 816A has a first terminal coupled to the second terminal of the switch 806A and a second terminal to receive AVSS. The capacitor 818A has a first terminal coupled to the second terminal of the switch 814A and a second terminal to receive AVSS.

The SCF circuitry 804B is a mirrored version of the SCF circuitry 804A. Accordingly, the switches 806B, 810B, 812B, and 814B, and the capacitors 808B, 816B, and 818B connect to one another and function in the same way as the switches 806A, 810A, 812A, and 814A, and the capacitors 808A, 816A, and 818A. However, while the second terminal of the switch 810A receives AVSS and the second terminal of the switch 812A receives AVDD, the second terminal of the switch 810B receives AVDD and the second terminal of the switch 812B receives AVSS. Thus, in the example of FIG. 8, the sampler PD circuitry 106 implements two instances of the foregoing SCF circuitry to support differential signaling. In other examples, the sampler PD circuitry 106 implements only one instance of the extender circuitry of FIG. 8 and supports single-ended signaling.

Within the SCF circuitry 804A, the switches 806A and 814A and the capacitors 816A and 818A implement the same track and hold architecture as the switches 314A and 318A and the capacitors 316A and 320A of the SCF circuitry 304A. Thus, the transfer function 704 also quantifies the gain of the SCF circuitry 304A presuming the values of the capacitors 816A and 818A are equal. However, the SCF circuitry 804A also includes the capacitor 808A, which switches between receiving AVSS and AVDD at its second terminal based on the phase of the CLK_FBK signals. The additional capacitor 808A adds an offset voltage with a value given by equation (8):

$$offset voltage = ( AVDD - AVSS ) ( \frac{{C}_{0}}{{C}_{0} + {C}_{1}} ) \qquad ( 9 )$$

In equation (9), C₀ is the value of the capacitor 808A and C₁ is the value of the capacitor 816A. Without the foregoing offset voltage, the SCF circuitry 304A would sample the rise time of the CLKB_REF signal halfway in between V0 and V1 if the CLK_FBK signal has no phase error. The point in time where the sample occurs without phase error is the quiescent point of the sampler PD circuitry. Because sampling occurs after the quiescent point when phase error is present, there is a chance that feedback edge movement is sampled in the nonlinear, asymptotic region that exists near V1 as described above.

The offset voltage introduced by the SCF circuitry 804 shifts the quiescent point earlier in time. Thus, if there is no phase error between the CLK_REF and CLK_FBK signals, the SCF circuitry 804A samples the rising edge of the CLKB_REF signal at a voltage that is closer to V0 than it is to V1. Advantageously, the change in voltage is comparatively more linear at the beginning of the rise time window than the end of the rise time window due to the eventual saturation of the inverter architecture and the asymptotic approach to V1. Accordingly, the SCF circuitry 804A supports a greater amount of feedback edge movement (and therefore performs better) than the SCF circuitry 304A. However, the SCF circuitry 804A requires additional cost and area to implement compared to the SCF circuitry 304A due to the capacitor 808A, the switch 810A, the switch 812A, etc. Accordingly, a manufacturer or designer that implements the sampler PD circuitry 106 using the examples described herein can choose one of the SCF circuitry 304 or 804 as shown in FIGS. 3 and 8 based on which implementation best meets the performance, cost, and area requirements of their particular use case. Furthermore, because any of the extender circuitry 302, 402, or 502 can be coupled to either of the SCF circuitry 304 or 804, the examples described herein provide six implementations of the sampler PD circuitry 106 that each have a unique combination of performance, cost, and area.

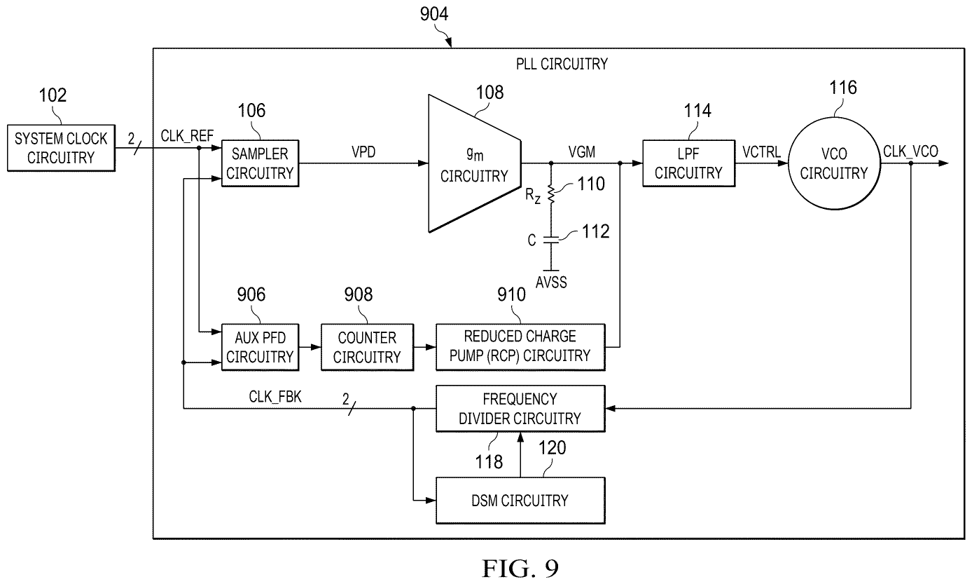

FIG. 9 is a block diagram of a second example implementation of PLL circuitry. The PLL circuitry 904 shown in the example of FIG. 9 includes the sampler PD circuitry 106, the gₘ circuitry 108, the resistor 110, the capacitor 112, the LPF circuitry 114, the frequency divider circuitry 118, and the DSM circuitry 120 of FIG. 1, example Auxiliary Phase Frequency Detector (AUX PFD) circuitry 906, example counter circuitry 908, and example Reduced Charge Pump (RCP) circuitry 910.

Within the PLL circuitry 904, the sampler PD circuitry 106, the gₘ circuitry 108, the resistor 110, the capacitor 112, the LPF circuitry 114, the frequency divider circuitry 118, and the DSM circuitry 120 connect to one another in the same manner as described above. In such examples, the sampler PD circuitry 106 expresses the phase error as a voltage by sampling the extended rise time of the CLKB_REF and CLKZ_REF during their respective rise times. However, when the CLKB_REF and CLKZ_REF signals are not transitioning between voltages (for example, in the middle of a wavelength), the phase error cannot be sampled because a difference in phase does not correspond to a difference in voltage during such periods. As used above and herein, such windows of time are referred to as slewing regions.

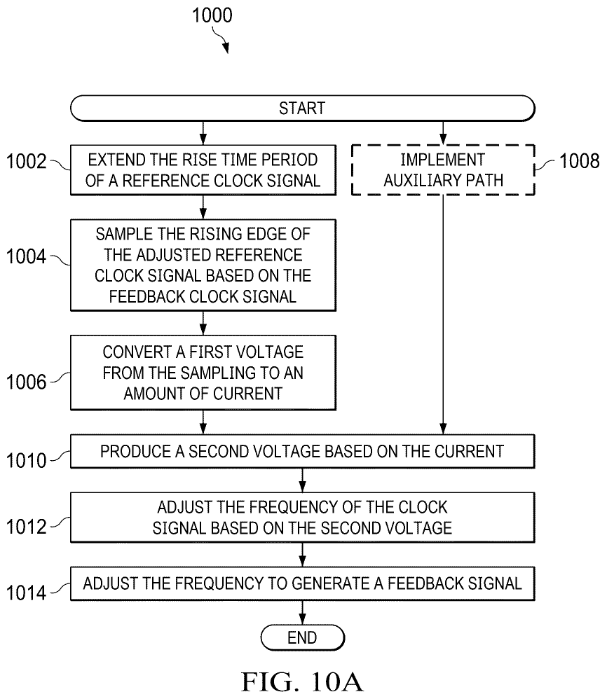

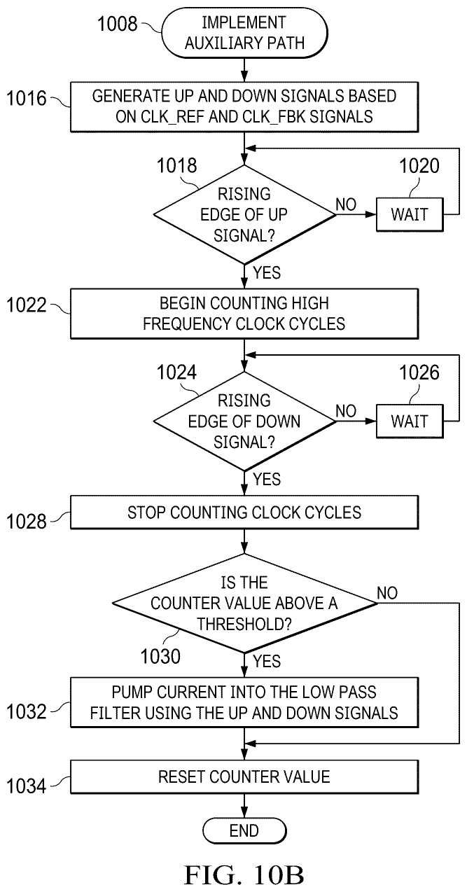

The PLL circuitry 904 mitigates the length of the slewing region by implementing a bang-bang auxiliary path formed by the AUX PFD circuitry 906 and the RCP circuitry 910. The AUX PFD circuitry 906 receives the same signals at its inputs as the sampler PD circuitry 106 (for example, the CLK_REF and CLK_FBK signals) and generates UP and DOWN signals at its outputs. The UP and DOWN signals quantify the polarity of the phase error as described further in connection with FIG. 10B. In some examples, the bang-bang control path is referred to as a hysteresis control path or a two-step control path.

The counter circuitry 908 has inputs coupled to the outputs of the AUX PFD circuitry 906 and outputs coupled to the inputs of the RCP circuitry 910. The counter circuitry 908 determines when the PLL circuitry 904 has entered a slewing region using the UP and DOWN signals. Once the PLL circuitry 904 enters a slewing region, the counter circuitry 908 forwards the UP and DOWN signals to the RCP circuitry 910.

The RCP circuitry 910 has inputs coupled to the outputs of the counter circuitry 908 and an output coupled to the input of the LPF circuitry 114. The RCP circuitry 910 pumps an amount of current into the LPF circuitry 114 based on the polarity of the phase error quantified by the UP and DOWN signals. The rate at which the value of VCTRL changes is responsive to the additional current provided at the input of LPF circuitry 114, thereby changing the CLK_VCO and CLK_FBK signals and exiting the slewing region faster.

Notably, the RCP circuitry 910 is referred to as ‘reduced’ in FIG. 9 because it requires only a main path for current to flow. This main path is implemented by a current source, an UP switch coupled to the LPF circuitry 114, a DOWN switch, and a current sink. In contrast, the known CP architectures described above include all of the foregoing components and also includes a second UP switch, a second DOWN switch, and buffer circuitry implemented with a rail-to-rail amplifier. The additional circuitry is required in known CP architectures so that the current from the current source can be dumped into a dummy path whenever it is not flowing into the LPF circuitry. A dummy node is not necessary in the examples described herein, however, because the RCP circuitry 910 only pumps current into the LPF circuitry 114 during a slewing region window. Therefore, the main feed forward path (for example, the sampler PD circuitry 106 and the gₘ circuitry 108) uses the current that would have otherwise flown into a dummy node to a) sample the CLK_REF signal during an extended rise time and b) convert the sampled voltage into a current as described above. When compared to the RCP circuitry 910, the dummy node used in known CP architectures adds complexity, consumes additional power, and requires significant additional space on an IC to implement.

In general, the PLL circuitry 904 of FIG. 9 a) performs better, b) costs more to implement, and c) requires more space to implement, than the PLL circuitry 104 of FIG. 9 due to the auxiliary path described above. Accordingly, a manufacturer or designer that implements PLL circuitry using the examples described herein can choose one of the architectures of FIGS. 1, 9 based on based on which implementation best meets the performance, cost, and area requirements of their particular use case. Both the PLL circuitry 104 and 904 can be implemented using of the six possible implementations of the sampler PD circuitry 106 described above in FIGS. 3, 4, 5, and 8.

FIGS. 10A and 10B is a flowchart representative of example operations 1000 that may be at least one of executed, instantiated, or performed by the PLL circuitry 104 or 904 to generate clock signals. The example operations 1000 of FIGS. 10A and 10B begin when the sampler PD circuitry 106 extends the rise time period of a reference clock signal. (Block 1002). The reference clock signal is produced by the system clock circuitry 102 and is referred to as CLK_REF as described above. The operations of block 1002 may be performed by any one of the extender circuitry 302, 402, or 502 as described above.

The sampler PD circuitry 106 samples the rising edge of the adjusted reference clock signal (for example, CLKB_REF and CLKZ_REF) based on a feedback signal (for example, CLK_FBK). (Block 1004). The phase of the feedback signal is ideally equal to the phase of the original reference clock signal as described above. However, the phase of the CLK_FBK signal can vary from clock cycle to clock cycle due to error in the feedback loop of the PLL circuitry. Thus, the extension of the rise time window at block 1002 ensures that the sampling at block 1004 occurs when the voltage of the CLKB_REF and CLKZ_REF changes linearly over time, thereby properly quantifying the possible feedback edge movement that occurs due to the error. The operations of block 1004 may be performed by either of the SCF circuitry 304 or 804 as described above.

The gₘ circuitry 108 converts a first voltage from the sampling of block 1004 to an amount of current. (Block 1006). The gₘ circuitry 108 may be implemented using any suitable circuit architecture.

In examples where the PLL circuitry 904 implements the operations 1000, the AUX PFD circuitry 906, the counter circuitry 908, and the RCP circuitry 910 implement the auxiliary path. (Block 1008). The foregoing components implement the auxiliary path in parallel with the primary feed forward path of blocks 902-908. In examples where the PLL circuitry 104 implements the operations 1000 instead of the PLL circuitry 904, the operations of block 1008 are not performed. Block 1008 is described further in connection with FIG. 10B.

After block 1006, and also after block 1008 in some examples, the LPF circuitry 114 produces a second voltage based on the amount of current. (Block 1010). The LPF circuitry 114 also removes high frequency energy within the signal provided from the gₘ circuitry 108. In some examples, the LPF circuitry 114 also receives high frequency energy from a signal provided by the RCP circuitry 910. The LPF circuitry 114 may be implemented using any suitable architecture, including a resistor-capacitor cascade.

The VCO circuitry 116 adjusts the frequency of a generated clock signal based on the second voltage. (Block 1012). The generated clock signals may be used for any purpose, including but not limited to serializer or deserializer operations within the example FPD context described above.

The frequency divider circuitry 118 adjusts the frequency of the signal from block 1012 to generate a feedback signal. (Block 1014). In particular, the frequency divider circuitry 118 generates the FBK signal to have the same frequency as the CLK_REF signals so that the sampler PD circuitry 106 can compare the two and quantify the loop error. The operations 1000 end after block 1014.

FIG. 10B is a flowchart representative of operations 1000 that may be at least one of executed, instantiated, or performed by the PLL circuitry 904 to implement the auxiliary path of FIG. 10A. In particular, the flowchart of FIG. 10B is an example implementation of block 1008 of FIG. 10A.

Execution of block 1008 begins when the AUX PFD circuitry 906 generates UP and DOWN signals based on the CLK_REF and CLK_FBK signals. (Block 1016). In some examples, the AUX PFD circuitry 906 is implemented using a known PD architecture that includes two D-flip flops whose reset terminals couple to the same AND gate. Thus, the UP signal generated by the AUX PFD circuitry 906 goes to V1 at the rising edge of the CLK_REF signal. Similarly, the DOWN signal generated by the AUX PFD circuitry 906 goes to V1 at the rising edge of the CLK_FBK signal. In response to both the UP and DOWN signals being at V1, the AUX PFD circuitry 906 resets and transitions both the UP and DOWN signals back to V0. The AUX PFD circuitry 906 continues implementing block 1016, and thus continues to change the voltage of the UP and DOWN signals, throughout the example flowchart of FIG. 10B.

The counter circuitry 908 determines whether the UP signal has a rising edge. (Block 1018). A rising edge refers to a transition from V0 to V1 as described above. If the UP signal does not currently have a rising edge (Block 1018: No), the counter circuitry 908 waits for a period (Block 1020) before checking the UP signal at block 1018 again.

If the UP signal does have a rising edge (Block 1018: Yes), the counter circuitry 908 begins counting clock cycles of a high frequency signal. (Block 1022). The signal used by block 1108 is sufficiently high frequency that multiple clock cycles occur within the extended rise time of the CLKB_REF and CLKZ_REF signals. The counter circuitry 908 also begins to check for the rising edge of the DOWN signal (Block 1024). If the rising edge of the DOWN signal does not currently have a rising edge (Block 1024: No), the counter circuitry 908 waits for a period (Block 1026) before checking the DOWN signal at block 1024 again. Meanwhile the counter circuitry 908 continues to increment a counter value once per clock cycle while implementing the loop of blocks 1024 and 1026.

If the DOWN signal does have a rising edge (Block 1024: Yes), the counter circuitry 908 stops counting clock cycles. (Block 1028). The counter circuitry 908 then determines whether the counter value is above a threshold. (Block 1030). If the counter value is above the threshold (Block 1030: Yes), then the difference in phase between the CLK_REF and CLK_FBK signals is sufficiently far apart in time to indicate the PLL circuitry 104 or 904 has entered the slewing region. Accordingly, in such examples, the RCP circuitry 910 pumps current into the LPF circuitry 114 using the UP and DOWN signals. (Block 1032). The RCP circuitry 910 implements block 1032 by starting to provide current at the rising edge of the UP signal and stopping the flow of current at the rising edge of the DOWN signal. Alternatively, if the counter is not above the threshold (Block 1030: No), then the PLL circuitry 104 or 904 has not entered the slewing region and block 918 is not implemented.

After block 1118, if the counter is not above the threshold (Block 1030: No), the counter circuitry 908 resets the counter value. (Block 1034). Control returns to block 1010 of FIG. 10A after block 1120. More generally, the components of PLL circuitry 104 or 904 may continue to implement one or more of blocks 1002-1034 continuously and in parallel with one another so long as the PLL circuitry 104 or 904 remains powered ON.

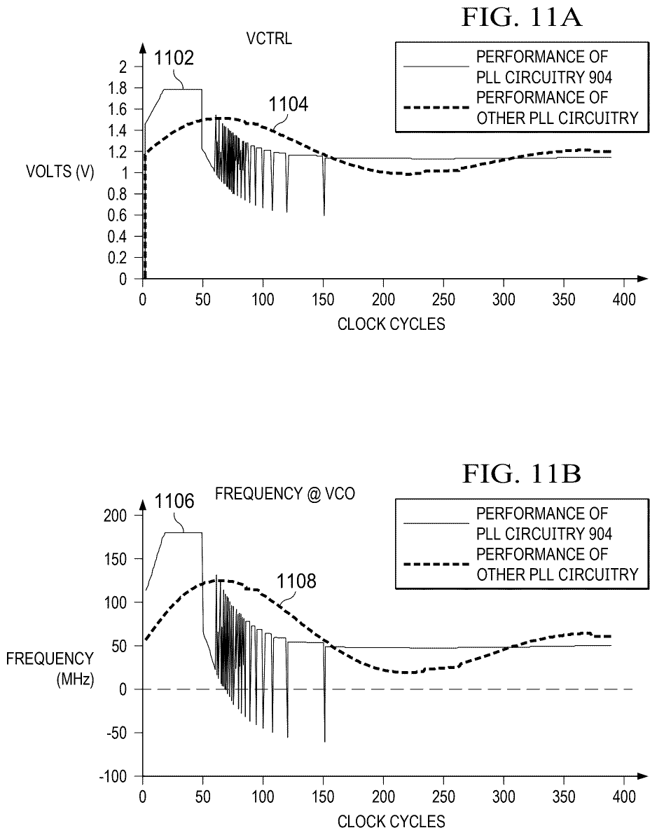

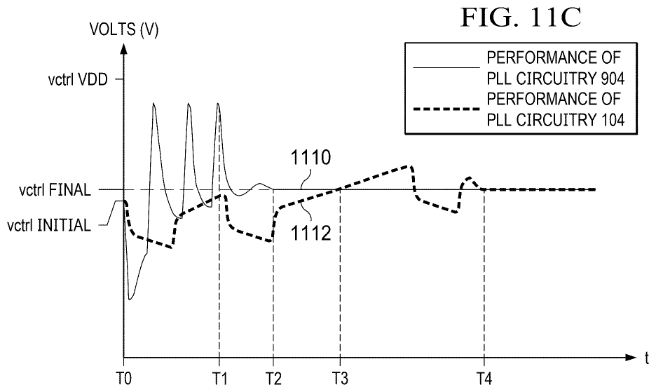

FIGS. 11A, 11B, and 11C are graphs of an example performance of the PLL circuitry 904 of FIG. 9. The graph of FIG. 11A includes example signals 1102 and 1104. The signal 1102 represents VCTRL (for example, the signal generated by LPF circuitry 114) within the PLL circuitry 904 described herein and the signal 1104 represents VCTRL within a known PLL architecture at the same bandwidth. The x axis represents time as measured in clock cycle and the y axis represents the voltage of the VCTRL signal in volts.

In the example of FIG. 11A, the initial phase error between the reference and feedback clocks is one twentieth of the reference clock period. The signal 1102 shows that, after the initial phase error is introduced at x=0, the PLL circuitry 904 settles to a steady state voltage of 1.2 V at approximately 150 clock cycles. In comparison, the signal 1104 shows that VCTRL in known PLL architectures at the same bandwidth and input condition require over 400 clock cycles to settle at the 1.2 V steady state voltage.

The graph of FIG. 11B includes example signals 1106 and 1108. The signal 1106 represents the frequency error at the VCO circuitry 116 within the PLL circuitry 904 described herein. Similarly, the signal 1108 represents the frequency at the VCO circuitry 116 within a known PLL architecture at the same bandwidth. The x axis represents time as measured in clock cycle and the y axis represents frequency as measured in Megahertz (MHz).

In the example of FIG. 11B, the initial phase error between the reference and feedback clocks is one half of the reference clock period. The signal 1106 shows that, after the initial phase error is introduced at x=0, the PLL circuitry 904 settles to a steady state of 50 MHz at approximately 150 clock cycles. In comparison, the signal 1108 shows that known PLL architectures at the same bandwidth and input condition require over 400 clock cycles to settle at the 50 MHz steady state.

The graph of FIG. 11C includes example signals 1110 and 1112. Like the signal 1102, the signal 1110 also represents VCTRL within the PLL circuitry 904 of FIG. 9 (e.g., PLL circuitry described herein that includes the auxiliary path). The signal 1112 represents VCTRL the PLL circuitry 104 of FIG. 1 (e.g., PLL circuitry described herein without an auxiliary path). The x axis represents time and includes timestamps T0, T1, T2, T3, and T4. The indices of the timestamps are ordered chronologically. The y axis represents the value of the VCTRL signal in Volts.

In the example of FIG. 11C, the frequency of the CLK_REF signal increases for both PLL circuits at TO. Accordingly, both PLL circuits seek to increase the frequency of the CLK_VCO signal by increasing the value of VCTRL signal from “VCTRL initial” to “VCTRL final” as labeled on the y axis. Comparing signals 1110 and 1112 shows that the additional current provided by the auxiliary path enables the magnitude of VCTRL to increase more between T0 and T1 than it would without the auxiliary path.

At T2, the signal 1110 shows that the auxiliary path has locked onto the desired settle state of “VCTRL final”. T2 also shows an example of a steep increase in the value of VCTRL in the signal 1112. Such rapid changes to VCTRL occur during the extended time rise period produced by the sampler PD circuitry 106.

The signal 1112 increases slowly and linearly for a period around T3. During this time, the sampler PD circuitry 106 of the PLL circuitry 104 is slowly approaching the slewing region because the rate of current change is limited by the gₘ circuitry 108. The sampler PD circuitry 106 of the PLL circuitry 104 is also continuously sampling the extended rise time window during the period around T3.

In the example of FIG. 11C, the signal 1112 shows that PLL circuitry described herein without the auxiliary path settles at “VCTRL final” at T4. In contrast, the signal 1110 shows that PLL circuitry described herein with the auxiliary path settles at T2 when receiving the same input conditions. More generally, the inclusion of the auxiliary path in the PLL circuitry described herein increases performance by locking the feedback loop faster. Furthermore, while the inclusion of the auxiliary path adds cost and space on an IC as described above, the space and cost required to implement the PLL circuitry 904 is significantly smaller than the space and cost required to implement a known PLL architecture with known PFD circuitry and known CP circuitry.

FIG. 12 is a block diagram of an example vehicle 1200 including an example advanced driver-assistance (ADAS) system 1205 and an example in-vehicle infotainment (IVI) system 1210. The ADAS system 1205 and the IVI system 1210 may be referred to as flat panel display (FPD) link systems that may display media, such as images, multi-media content, etc. In some examples, the vehicle 1200 may include one or more instances of the ADAS system 1205 or the IVI system 1210. For example, the vehicle 1200 may include one or more instances of the ADAS system 1205 without the IVI system 1210. In another example, the vehicle 1200 may include one or more instances of the IVI system 1210 without the ADAS system 1205. In yet another example, the vehicle 1200 may include one or more instances of the ADAS system 1205 and one or more instances of the IVI system 1210. In the example of FIG. 12, the vehicle 1200 is illustrated as a system for traversing distances, such as a car, a truck, etc. Alternatively, the vehicle 1200 may be replaced, illustrated, or described as an alternative distributed display system, such as a boat, airplane, spacecraft, workstation, control panel, etc.

The ADAS system 1205 of FIG. 12 includes an example ADAS hub 1215, a first example peripheral module 1220, a second example peripheral module 1225, a third example peripheral module 1230, a fourth example peripheral module 1235, and an example display 1240. Alternatively, the ADAS system 1205 may include any number of peripheral module(s) or display(s).

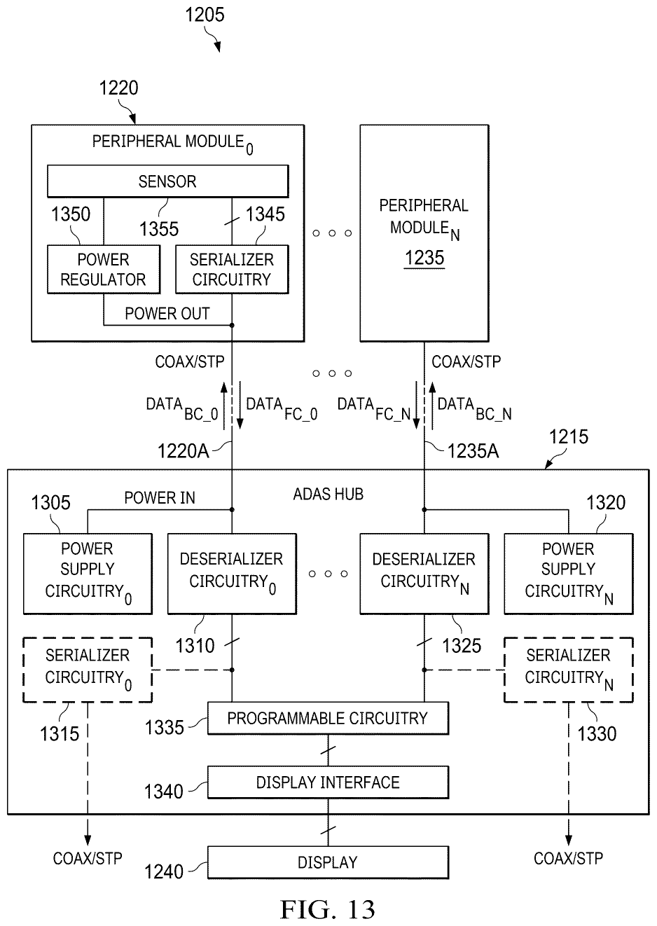

The ADAS system 1205 is an example type of FPD-link system that utilizes serializing and deserializing data for driving assistance in the vehicle 1200. In some examples, the ADAS system 1205 utilizes serializing and deserializing media for an alternative implementation of processing, storing, or displaying data, such as a security system, recording system, etc. In some examples, the ADAS system 1205 is an example camera system that facilitates at least one of the storing, processing, or displaying multi-media data (for example, images, videos, etc.) from one or more sensors, such as cameras. In other examples, the ADAS system 1205 may facilitate at least one of the storing, processing, or displaying an alternative type of data from one or more alternative types of sensors (for example, lidar, radar, ultrasonic, etc.). An example of the ADAS system 1205 is further illustrated and described in connection with FIG. 13.

The ADAS hub 1215 is communicatively coupled to the peripheral modules 1220, 1225, 1230, 1235 and the display 1240. The ADAS hub 1215 uses full duplex communications to transmit data to and receive data from the peripheral modules 1220, 1225, 1230, 1235. In some examples, the ADAS hub 1215 uses low-voltage differential signaling (LVDS) to communicate with the peripheral modules 1220, 1225, 1230, 1235. Alternatively, the ADAS hub 1215 may use an alternative type of signaling to communicate with the peripheral modules 1220, 1225, 1230, 1235, such as display serial interface (DSI), embedded display port (eDP), etc. The ADAS hub 1215 may at least one of store, process, or display data from the peripheral modules 1220, 1225, 1230, 1235. In the example of FIG. 12, the ADAS hub 1215 displays the data from one or more of the peripheral modules 1220, 1225, 1230, 1235 using the display 1240. The ADAS hub 1215 uses multi-lane signaling to display data using the display 1240. Also, the ADAS hub 1215 may also at least one of store or process data from the peripheral modules 1220, 1225, 1230, 1235 for other functions of the vehicle 1200, such as object recognition, time of flight calculations, etc. An example of the ADAS hub 1215 is further illustrated and described in connection with FIG. 13.

The peripheral modules 1220, 1225, 1230, 1235 are communicatively coupled to the ADAS hub 1215. The peripheral modules 1220, 1225, 1230, 1235 include at least one sensor that receives information of the surrounding environment, such as images, videos, time of flight measurements, beamforming data, etc. The peripheral modules 1220, 1225, 1230, 1235 transmit the received sensor data to the ADAS hub 1215 using communication channels 1220A, 1225A, 1230A, 1235A. In some examples, the communication channels 1220A, 1225A, 1230A, 1235A are coaxial connectors, which couple the ADAS hub 1215 to the peripheral modules 1220, 1225, 1230, 1235. In such examples, the ADAS hub 1215 supplies power to the peripheral modules 1220, 1225, 1230, 1235 using power over coax (POC) across the communication channels 1220A, 1225A, 1230A, 1235A. Alternatively, the communication channels 1220A, 1225A, 1230A, 1235A may be formed by a different type of connector, such as a standard twisted pair (STP). An example of the peripheral modules 1220, 1225, 1230, 1235 are further illustrated and described in connection with FIG. 13.

In example operation of the ADAS system 1205 of FIG. 12, the peripheral modules 1220, 1225, 1230, 1235 produce video streams of the environment surrounding the vehicle 1200. The peripheral modules 1220, 1225, 1230, 1235 serialize data of the video streams. The peripheral modules 1220, 1225, 1230, 1235 transmit the serial data streams to ADAS hub 1215 using the communication channels 1220A, 1225A, 1230A, 1235A. Concurrently, the ADAS hub 1215 may transmit data to the peripheral modules 1220, 1225, 1230, 1235 using the communication channels 1220A, 1225A, 1230A, 1235A. Communications between the ADAS hub 1215 and the peripheral modules 1220, 1225, 1230, 1235 may occur simultaneously. Such multi-directional communications across the same one of the communication channels 1220A, 1225A, 1230A, 1235A are referred to as full duplex communications.

In such example operations of the ADAS system 1205 of FIG. 12, the ADAS hub 1215 receives the serial data streams from the peripheral modules 1220, 1225, 1230, 1235. The ADAS hub 1215 deserializes the data streams to reconstruct the video streams captured by the peripheral modules 1220, 1225, 1230, 1235. The ADAS hub 1215 at least one of stores, processes, or displays the video streams for driver assistance. For example, the ADAS hub 1215 displays the video stream of the peripheral module 1235 on the display 1240 responsive to a determination that the perspective corresponding to the peripheral module 1235 is needed. In another example, the ADAS hub 1215 stores or process video streams of the peripheral modules 1220, 1225, 1230, 1235 for detecting safety hazards in the environment of the vehicle 1200.

Example operations of the ADAS system 1205 are further described in connection with FIG. 13. Advantageously, serializing and deserializing data from the peripheral modules 1220, 1225, 1230, 1235 reduces the number of connections within the vehicle 1200 to the ADAS hub 1215. Advantageously, the serial data streams are capable of accurately traversing relatively large distances across the communication channels 1220A, 1225A, 1230A, 1235A.

The IVI system 1210 of FIG. 12 includes an example media source 1245, example IVI driver circuitry 1250, a first example display driver 1255, a first example display 1260, a second example display 1265, a second example display driver 1270, and a third example display 1275. Alternatively, the IVI system 1210 may include any number of display driver(s) or display(s).

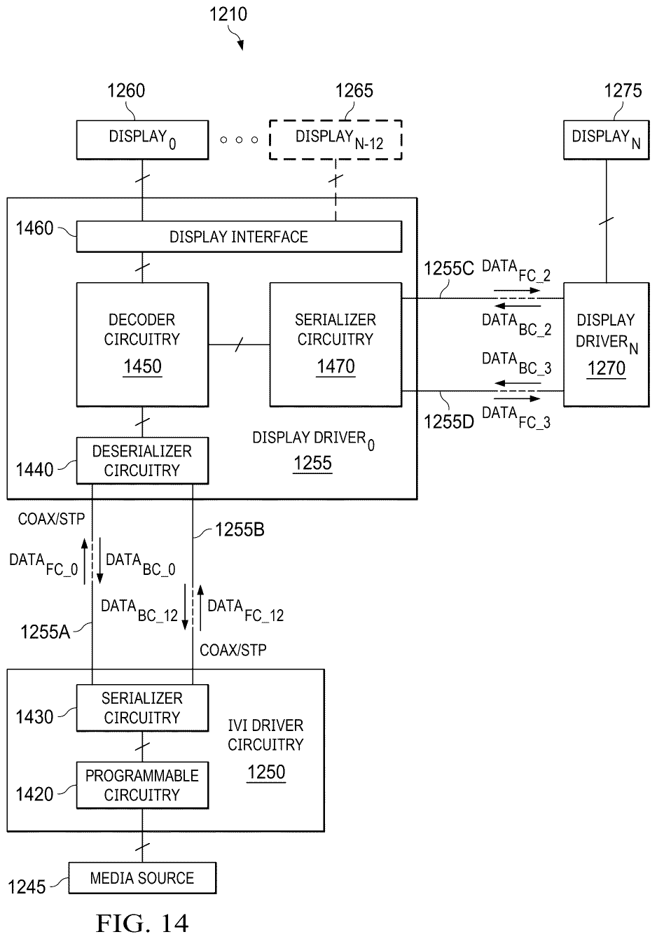

The IVI system 1210 is an example type of FPD-link system that utilizes serializing and deserializing media for infotainment on one or more displays (for example, the displays 1260, 1265, 1275). In some examples, the IVI system 1210 is a dashboard having multiple displays for displaying content. In other examples, the IVI system 1210 is a different display system having multiple displays for displaying content, such as a studio, workstation, etc. In the example of FIG. 12, the IVI system 1210 includes the media source 1245, the IVI driver circuitry 1250, the display drivers 1255, 1270, and the displays 1260, 1265, 1275. Alternatively, the IVI system 1210 may include any number of media source(s), display driver(s), or display(s). An example of the IVI system 1210 is further illustrated and described in connection with FIG. 14.

In the IVI system 1210, the media source 1245 is coupled to the IVI driver circuitry 1250. The media source 1245 supplies media to the IVI driver circuitry 1250 for display on one or more of the displays 1260, 1265, 1275. In some examples, the media source 1245 is integrated in the vehicle 1200, such as circuitry supporting a data stream or memory storing media. In other examples, the media source 1245 represents a connection to a device that is external to the vehicle 1200, such as a wireless connection to a service hosting a multi-media stream.

The IVI driver circuitry 1250 is communicatively coupled to the media source 1245 and the display driver 1255. The IVI driver circuitry 1250 processes multi-media data from the media source 1245 for transmission to one or more of the display drivers 1255, 1270. The IVI driver circuitry 1250 uses full duplex communications to transmit data to and receive data from the display driver 1255. In some examples, the IVI driver circuitry 1250 uses LVDS to communicate with the display driver 1255. In such examples, the IVI driver circuitry 1250 indirectly communicates with the display driver 1270 through the display driver 1255. Such an example is further illustrated and described in connection with FIG. 14. Alternatively, the IVI driver circuitry 1250 may use an alternative type of signaling to communicate with the display driver 1255, such as DSI, eDP, etc. An example of the IVI driver circuitry 1250 is further illustrated and described in connection with FIG. 14.

The display driver 1255 is communicatively coupled to the IVI driver circuitry 1250, the displays 1260, 1265, and the display driver 1270. The display driver 1255 interfaces with the IVI driver circuitry 1250 using first and second communication channels 1255A, 1255B. The display driver 1255 interfaces with the display driver 1270 using third and fourth communication channels 1255C, 1255D. In the example of FIG. 12, first and second coaxial connectors form the communication channels 1255A, 1255B between the IVI driver circuitry 1250 and the display driver 1255. Similarly, third and fourth coaxial connectors form the communication channels 1255C, 1255D between the display drivers 1255, 1270. The display driver 1255 uses multi-lane signaling to display media on the displays 1260, 1265. In some examples, the display driver 1255 decodes additional data from the IVI driver circuitry 1250 to determine which one of the displays 1260, 1265 corresponds to the data. Although the display driver 1255 of FIG. 12 is coupled to the displays 1260, 1265, the display driver 1255 may be coupled to any number of display(s). An example of the display driver 1255 is further illustrated and described in connection with FIG. 14.

The display driver 1270 is communicatively coupled to the display driver 1255 and the display 1275. In some examples, the display driver 1270 may be coupled to another instance of the display driver 1270 (similar to the communication channels 1255A, 1255B, 1255C, 1255D of the display driver 1255). The display driver 1270 interfaces with the display driver 1255 using the communication channels 1255C, 1255D. The display driver 1270 uses multi-lane signaling to display multi-media data using the display 1275. Although the display driver 1255 of FIG. 12 is coupled to the display 1275, the display driver 1270 may be coupled to any number of display(s).

In an example operation of the IVI system 1210 of FIG. 12, the media source 1245 supplies media for display on at least one of the displays 1260, 1265, 1275. The IVI driver circuitry 1250 determines one or more of the displays 1260, 1265, 1275 to display the media from the media source 1245. The IVI driver circuitry 1250 determines which of the display drivers 1255, 1270 are coupled to the one or more of the displays 1260, 1265, 1275. The IVI driver circuitry 1250 generates an identifier(s) that specifies at least one of the one or more of the display drivers 1255, 1270 or one or more of the displays 1260, 1265, 1275. The IVI driver circuitry 1250 combines the identifying data and the media from the media source 1245. The IVI driver circuitry 1250 generates a serial data stream by serializing the combined data for transmission on at least one of the communication channels 1255A, 1255B.

In such example operations of the IVI system 1210, the display driver 1255 receives the serial data stream representing the media and identifying data. The display driver 1255 deserializes the serial data stream(s) from the communication channels 1255A, 1255B. The display driver 1255 decodes the identifying data to determine if the media corresponds to either of the displays 1260, 1265. If the display driver 1255 determines that the media corresponds to one or more of the displays 1260, 1265, the display driver 1255 displays the media on one or more of the displays 1260, 1265. If the display driver 1255 determines that the media does not correspond to one or more of the displays 1260, 1265, the display driver 1255 regenerates the serial data stream by reserializing the combined media and identifying data. The display driver 1255 transmits the serial data to the display driver 1270 via at least one of the communication channels 1255C, 1255D. After receiving the serial data stream from the communication channels 1255C, 1255D, the display driver 1255 deserializes the serial data stream(s). The display driver 1270 decodes the identifying data to determine if the media corresponds to the display 1275. If the display driver 1270 determines that the identifying data corresponds to the display 1275, the display driver 1270 displays the media on the display 1275. In some examples, the display drivers 1255, 1270 transmit serial data along the communication channels 1255A, 1255B, 1255C, 1255D to the IVI driver circuitry 1250. In such examples, the concurrent communications from the display drivers 1255, 1270 may confirm reception or display of the media on one or more of the displays 1260, 1265, 1275.

Example operations of the IVI system 1210 are further described in connection with FIG. 14. Serializing and deserializing media from the media source 1245 reduces the number of connections to the displays 1260, 1265, 1275 within the vehicle 1200. Also, the serial data streams are capable of accurately traversing relatively large distances across the communication channels 1255A, 1255B, 1255C, 1255D.

FIG. 13 is a block diagram of an example of the ADAS system 1205 of FIG. 12 including the ADAS hub 1215, the peripheral modules 1220, 1235, and the display 1240 of FIG. 12. The example ADAS hub 1215 of FIG. 13 includes first example power supply circuitry 1305, first example deserializer circuitry 1310, first example serializer circuitry 1315, second example power supply circuitry 1320, second example deserializer circuitry 1325, second example serializer circuitry 1330, example programmable circuitry 1335, and example display interface circuitry 1340. The example peripheral module 1220 of FIG. 13 includes example serializer circuitry 1345, example power regulator circuitry 1350, and an example sensor 1355.

The power supply circuitry 1305 has an output coupled to the communication channel 1220A and the deserializer circuitry 1310. In some examples, the power supply circuitry 1305 has an input coupled to a power storage or an electronic control unit (ECU), which supplies power. In other examples, the power supply circuitry 1305 is in the peripheral module 1220. In such examples, the power supply circuitry 1305 directly supplies power to the peripheral module 1220. Alternatively, a different method of powering the peripheral module 1220 may be used in the examples described herein.

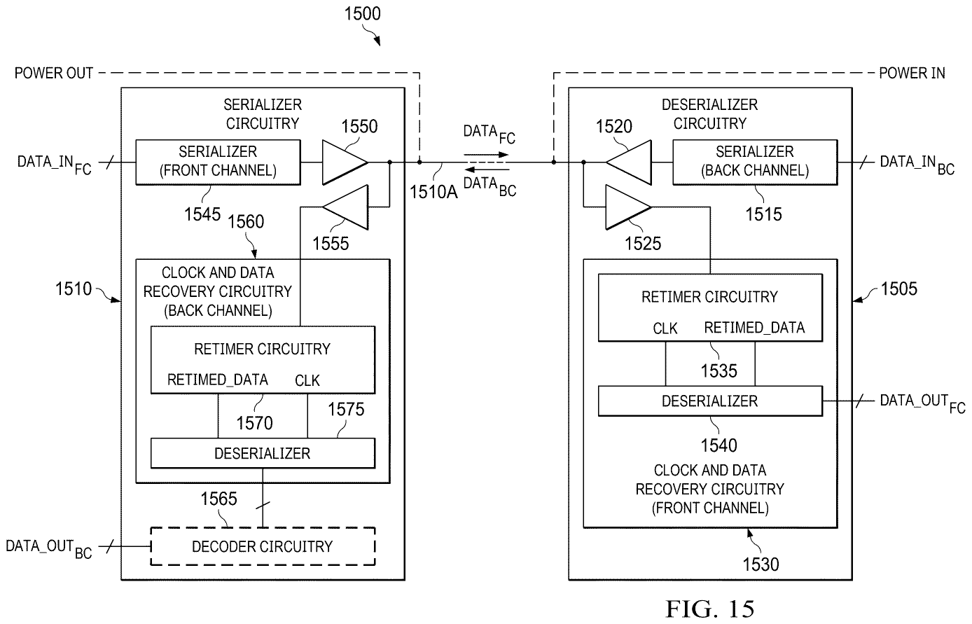

The deserializer circuitry 1310 has an input and outputs. The input of the deserializer circuitry 1310 is coupled to the communication channel 1220A and the power supply circuitry 1305. The outputs of the deserializer circuitry 1310 are coupled to the serializer circuitry 1315 and the programmable circuitry 1335. In some examples, the deserializer circuitry 1310 communicates with the peripheral module 1220 using serial data streams along the communication channel 1220A. An example of the deserializer circuitry 1310 is further illustrated and described in connection with FIG. 15.

The serializer circuitry 1315 has inputs and an output. The inputs of the serializer circuitry 1315 are coupled to the deserializer circuitry 1310 and the programmable circuitry 1335. The output of the serializer circuitry 1315 is structured to be coupled to an additional communication channel. In some examples, as illustrated by the dashed lines, the ADAS hub 1215 may include the serializer circuitry 1315 to connect the ADAS system 1205 to external circuitry. In such examples, the serializer circuitry 1315 may communicatively couple the ADAS system 1205 to another ADAS system, the IVI system 1210, storage medium, an ECU, etc. In other examples, the serializer circuitry 1315 may be excluded from the ADAS hub 1215.

The power supply circuitry 1320 has an output coupled to the communication channel 1235A and the deserializer circuitry 1325. In some examples, the power supply circuitry 1320 has an input coupled to a power storage or an ECU, which supplies power. In other examples, the power supply circuitry 1320 is in the peripheral module 1235. In such examples, the power supply circuitry 1320 directly supplies power to the peripheral module 1235. Alternatively, a different method of powering the peripheral module 1235 may be used in the examples described herein.

The deserializer circuitry 1325 has an input and outputs. The input of the deserializer circuitry 1325 is coupled to the communication channel 1235A and the power supply circuitry 1320. The outputs of the deserializer circuitry 1325 are coupled to the serializer circuitry 1330 and the programmable circuitry 1335. In some examples, the deserializer circuitry 1325 communicates with the peripheral module 1235 using serial data streams along the communication channel 1235A. An example of the deserializer circuitry 1325 is further illustrated and described in connection with FIG. 15.

The serializer circuitry 1330 has inputs and an output. The inputs of the serializer circuitry 1330 are coupled to the deserializer circuitry 1325 and the programmable circuitry 1335. The output of the serializer circuitry 1330 is structured to be coupled to an additional communication channel. In some examples, as illustrated by the dashed lines, the ADAS hub 1215 may include the serializer circuitry 1330 to connect the ADAS system 1205 to external circuitry. In such examples, the serializer circuitry 1330 may communicatively couple the ADAS system 1205 to another ADAS system, the IVI system 1210, storage medium, an ECU, etc. In other examples, the serializer circuitry 1330 may be excluded from the ADAS hub 1215.

The programmable circuitry 1335 has first inputs, second inputs, and outputs. The first inputs of the programmable circuitry 1335 are coupled to the deserializer circuitry 1310 and the serializer circuitry 1315. The second inputs of the programmable circuitry 1335 are coupled to the deserializer circuitry 1325 and the serializer circuitry 1330. The outputs of the programmable circuitry 1335 are coupled to the display interface circuitry 1340. In some examples, the programmable circuitry 1335 instantiates circuitry responsive to an execution of machine-readable instructions. In such examples, the programmable circuitry 1335 may be one of a central processing unit (CPU), a graphic processing unit (GPU), multi-core processing unit (MCU), etc. Alternatively, the programmable circuitry 1335 may be an application specific integrated circuit (ASIC) structured to at least one of store, process, or condition data from the deserializer circuitry 1310, 1325.

The display interface circuitry 1340 has inputs and outputs. The inputs of the display interface circuitry 1340 are coupled to the programmable circuitry 1335. The outputs of the display interface circuitry 1340 are coupled to the display 1240. In some examples, the display interface circuitry 1340 represents a display driver, which converts data from the programmable circuitry 1335 to drive the display 1240. In some such examples, the display interface circuitry 1340 may include a port and connector specific for driving the display 1240, such as a display port, a high-definition multimedia interface (HDMI) port, etc.

The serializer circuitry 1345 has inputs and an output. The inputs of the serializer circuitry 1345 are coupled to the sensor 1355. The output of the serializer circuitry 1345 is coupled to the communication channel 1220A and the power regulator circuitry 1350. In some examples, the serializer circuitry 1345 communicates with the ADAS hub 1215 using serial data streams along the communication channel 1220A. An example of the serializer circuitry 1345 is further illustrated and described in connection with FIG. 15.

In the example of FIG. 13, the deserializer circuitry 1310 is communicatively coupled to the serializer circuitry 1345 by a full duplex wireline connection represented by the communication channel 1220A. In some examples, both the deserializer circuitry 1310 and the serializer circuitry 1345 may receive data from or transmit data on the communication channel 1220A. In such examples, the input of the deserializer circuitry 1310 and the output of the serializer circuitry 1345 are bi-directional. Such an example is further described in connection with FIG. 15.

The power regulator circuitry 1350 has an input and an output. The input of the power regulator circuitry 1350 is coupled to the communication channel 1220A and the serializer circuitry 1345. The output of the power regulator circuitry 1350 is coupled to the sensor 1355. The power regulator circuitry 1350 receives power from the power supply circuitry 1305. In some examples, such as in FIG. 13, the power regulator circuitry 1350 receives power through the communication channel 1220A. In other examples, the power supply circuitry 1305 may be coupled to the power regulator circuitry 1350 by a separate connection or positioned in proximity to the peripheral module 1220.

The sensor 1355 has an input and outputs. The input of sensor 1355 is coupled to the power regulator circuitry 1350. The outputs of the sensor 1355 are coupled to the serializer circuitry 1345. In some examples, the sensor 1355 produces data corresponding to a surrounding environment. For example, in FIG. 12, the sensor 1355 may be a camera positioned to capture a portion of the environment surrounding the vehicle 1200. In another example, the sensor 1355 may be an alternative type of sensor for corresponding to characteristics of the surrounding environment of the vehicle 1200, such as obstacles.

In example operation, the power supply circuitry 1305 supplies power to the power regulator circuitry 1350 through the communication channel 1220A. In some examples, such as the communication channel 1220A being a coaxial connector, the power supply circuitry 1305 and the power regulator circuitry 1350 implement power over coax (POC). In such examples, the power supply circuitry 1305 supplies power (POWER IN) and the power regulator circuitry 1350 receives power (POWER OUT). The power regulator circuitry 1350 powers the sensor 1355, or more generally the peripheral module 1220 based on power from the power supply circuitry 1305. Similarly, the power supply circuitry 1320 may utilize the communication channel 1235A to supply power to the peripheral module 1235.

The sensor 1355 generates data corresponding to the surrounding environment. In some examples, the sensor 1355 is a camera that produces multimedia data corresponding to a perspective of the surrounding environment. In another example, the sensor 1355 is a lidar device that produces time of flight data corresponding to potential obstacles in the surrounding environment. In yet another example, the sensor 1355 is a radar that produces beamforming data corresponding to the surrounding environment. Alternatively, the sensor 1355 may be an alternative type of sensor that produces an alternative type of data. In such example operations, the sensor 1355 produces sensor data using multiple parallel data paths (also referred to as lines or lanes). The serializer circuitry 1345 serializes data of the multiple parallel data paths to produce a serial data stream having a data rate greater than the data rate of the parallel data paths from the sensor 1355. The serializer circuitry 1345 transmits the serial data stream to the deserializer circuitry 1310 using a front channel of the communication channel 1220A. Such data of the serial data stream is referred to as front channel data (DATA_{FC_0}).

In example operation, the deserializer circuitry 1310 receives the serial data stream after traversing the communication channel 1220A. Concurrently, the deserializer circuitry 1310 may transmit a serial data stream to the serializer circuitry 1345 using a back channel of the communication channel 1220A. Such data is referred to as back channel data (DATA_{BC_0}). In such examples, the front channel data has a data rate greater than the back channel data to reduce interference. Such multi-directional communications along the communication channel 1220A are referred to as full-duplex communications. The deserializer circuitry 1310 may use the back channel of the communication channel 1220A to control settings of the sensor 1355 or verify reception of data on the front channel. Similarly, the peripheral module 1235 and the deserializer circuitry 1325 may utilize full-duplex communications along the communication channel 1235A to exchange front and back channel data (DATA_{FC_N}, DATA_{BC_N}).

In example operation, the deserializer circuitry 1310 deserializes the front channel data to produce multiple parallel data paths. In some examples, the deserializer circuitry 1310 may decode identifying data from the front channel data. In such examples, the serializer circuitry 1315 may serialize and transmit the front channel data to external circuitry responsive to the deserializer circuitry 1310 decoding identifying data corresponding to external circuitry. Advantageously, the serializer circuitry 1315 allows the ADAS system 1205 to be coupled to another instance of the ADAS system 1205, the IVI system 1210, or alternative type of data processing system.

In example operation, the programmable circuitry 1335 at least one of processes, stores, or conditions the data of the multiple parallel data paths for the display 1240. In some examples, the programmable circuitry 1335 combines data from the peripheral modules 1220, 1235 prior to display. For example, the programmable circuitry 1335 may stitch video streams from the peripheral modules 1220, 1235 to display a larger portion of the surrounding environment. In such examples, the display interface circuitry 1340 structures the data from the programmable circuitry 1335 to drive the display 1240. In some examples, the display interface circuitry 1340 is at least one of a column pixel driver or a row pixel driver. The display 1240 produces a perceivable representation of the data from at least one of the peripheral modules 1220, 1235.

Example operations of the serializer and deserializer system of the ADAS system 1205 are further described in connection with FIG. 15. Advantageously, serializing and deserializing data from the peripheral modules 1220, 1235 reduces the number of connections to the ADAS hub 1215. Advantageously, the serial data streams are capable of accurately traversing relatively large distances across the communication channels 1220A, 1235A.

FIG. 14 is a block diagram of an example of the IVI system 1210 of FIG. 12. The IVI system 1210 of FIG. 14 includes the media source 1245, the IVI driver circuitry 1250, the example of the display driver 1255, 1270, and the displays 1260, 1265, 1275 of FIG. 12. The example IVI driver circuitry 1250 of FIG. 14 includes example programmable circuitry 1420 and example serializer circuitry 1430. The example display driver 1255 of FIG. 14 includes example deserializer circuitry 1440, example decoder circuitry 1450, example display interface circuitry 1460, and example serializer circuitry 1470.

The programmable circuitry 1420 has an input and outputs. The input of the programmable circuitry 1420 is coupled to the media source 1245. The outputs of the programmable circuitry 1420 are coupled to the serializer circuitry 1430. In some examples, the programmable circuitry 1420 instantiates circuitry responsive to the execution of machine-readable instructions. In such examples, the programmable circuitry 1420 may be one of a CPU, a GPU, an MCU, etc. Alternatively, the programmable circuitry 1335 may be an ASIC structured to at least one of store, process, or condition data from the media source 1245.

The serializer circuitry 1430 has inputs, a first output, and a second output. The inputs of the serializer circuitry 1430 are coupled to the programmable circuitry 1420. The first output of the serializer circuitry 1430 is coupled to the communication channel 1255A. The second output of the serializer circuitry 1430 is coupled to the communication channel 1255B. In some examples, the serializer circuitry 1430 communicates with the display driver 1255 using serial data streams along the communication channels 1255A, 1255B. An example of the serializer circuitry 1430 is further illustrated and described in connection with FIG. 15. Unlike the serializer circuitry 1345 of FIG. 13, the serializer circuitry 1430 exchanges data using multiple serial data streams along the communication channels 1255A, 1255B. In some examples, the serializer circuitry 1430 may be illustrated and described as a plurality of instances of the serializer circuitry 1430 supporting a single one of the communication channels 1255A, 1255B. For example, the serializer circuitry 1430 may be separated into two instances of the serializer circuitry 1430.

The deserializer circuitry 1440 has a first input, a second input, and outputs. The first input of the deserializer circuitry 1440 is coupled to the communication channel 1255A. The second input of the deserializer circuitry 1440 is coupled to the communication channel 1255B. The outputs of the deserializer circuitry 1440 are coupled to the decoder circuitry 1450. In some examples, the deserializer circuitry 1440 communicates with the IVI driver circuitry 1250 using serial data streams along the communication channels 1255A, 1255B. An example of the deserializer circuitry 1440 is further illustrated and described in connection with FIG. 15. Unlike the deserializer circuitry 1310, 1325 of FIG. 13, the deserializer circuitry 1440 exchanges data using multiple serial data streams along the communication channels 1255A, 1255B. In some examples, the deserializer circuitry 1440 may be illustrated and described as a plurality of instances of the deserializer circuitry 1440 supporting a single one of the communication channels 1255A, 1255B. For example, the deserializer circuitry 1440 may be separated into two instances of the deserializer circuitry 1440, such as the deserializer circuitry 1310, 1325 of FIG. 13.

The decoder circuitry 1450 has inputs, first outputs, and second outputs. The inputs of the decoder circuitry 1450 are coupled to the deserializer circuitry 1440. The first outputs of the decoder circuitry 1450 are coupled to the display interface 1460. The second outputs of the decoder circuitry 1450 are coupled to the serializer circuitry 1470. In some examples, the decoder circuitry 1450 is implemented using programmable circuitry or an ASIC. In such examples, the decoder circuitry 1450 is structured to route data from the deserializer circuitry 1440 to at least one of the display interface 1460 or the serializer circuitry 1470 responsive to the decoded portions of the data. Such portions of the data from the deserializer circuitry 1440 may be referred to as identifying data, which specifies one or more of the displays 1260, 1265, 1275 to display the media on.

The display interface 1460 has inputs, first outputs, and second outputs. The inputs of the display interface 1460 are coupled to the decoder circuitry 1450. The first outputs of the display interface 1460 are coupled to the display 1260. The second outputs of the display interface 1460 are coupled to the display 1265. In some examples, the display interface 1460 drives one or more of the displays 1260, 1265 responsive to data from the decoder circuitry 1450. In some such examples, the display interface 1460 may include a port and connector specific for driving the displays, such as a display port, an HDMI port, etc. In the example of FIG. 14, the display interface 1460 drives the displays 1260, 1265. Alternatively, the display driver 1255 may include any number of display interfaces 1460 for driving any number of displays, such as the displays 1260, 1265.

The serializer circuitry 1470 has inputs, a first output, and a second output. The inputs of the serializer circuitry 1470 are coupled to the decoder circuitry 1450. The first output of the serializer circuitry 1470 is coupled to the communication channel 1255C. The second output of the serializer circuitry 1470 is coupled to the communication channel 1255D. In some examples, the serializer circuitry 1470 communicates with the display driver 1270 using serial data streams along the communication channels 1255C, 1255D. An example of the serializer circuitry 1470 is further illustrated and described in connection with FIG. 15. Similar to the serializer circuitry 1430, the serializer circuitry 1470 exchanges data using multiple serial data streams along the communication channels 1255C, 1255D. In some examples, the serializer circuitry 1470 may be illustrated and described as a plurality of instances of the serializer circuitry 1470 supporting one of the communication channels 1255C, 1255D. For example, the serializer circuitry 1470 may be separated into two instances of the serializer circuitry 1470.

In example operation, the programmable circuitry 1420 receives multimedia data from the media source 1245. In some examples, the media source 1245 is internal to the IVI system 1210, such as memory storage, an ECU, a media stream, etc. In other examples, the media source 1245 is external to the IVI system 1210, such as a wireless connection to a service hosting a multi-media stream. The programmable circuitry 1420 identifies one or more of the displays 1260, 1265, 1275 that correspond to the data from the media source 1245. In some examples, the programmable circuitry 1420 encodes additional data onto the data from the media source 1245 corresponding to different operations of the IVI system 1210. For example, the programmable circuitry 1420 adds identifying data into portions of the data from the media source 1245 to specify one or more of the displays 1260, 1265, 1275 that correspond to the media. In such examples, the identifying data may specify the one or more of the displays 1260, 1265, 1275. The programmable circuitry 1420 supplies the data to the serializer circuitry 1430 for transmission to the display drivers 1255, 1270.

In example operation, the serializer circuitry 1430 receives data from the programmable circuitry 1420 on multiple parallel data paths. The serializer circuitry 1430 serializes data of the multiple parallel data paths to produce a first and second serial data stream having a data rate greater than the data rate of the parallel data paths from the programmable circuitry 1420. The serializer circuitry 1430 transmits the first serial data stream to the deserializer circuitry 1440 using a front channel of the communication channel 1255A. The data of the first serial data stream is referred to as first front channel data (DATA_{FC_0}). The serializer circuitry 1430 transmits the second serial data stream to the deserializer circuitry 1440 using a front channel of the communication channel 1255B. The data of the second serial data stream is referred to as second front channel data (DATA_{FC_1}). Advantageously, increasing the number of communication channels between the serializer circuitry 1430 and the deserializer circuitry 1440 increases the possible number of displays the IVI system 1210 may support at a given time.

In example operation, the deserializer circuitry 1440 receives the first and second serial data streams after traversing the communication channels 1255A, 1255B. Concurrently, the deserializer circuitry 1440 may transmit a first serial data stream to the serializer circuitry 1430 using a back channel of the communication channel 1255A. The data of the first serial data stream is referred to as first back channel data (DATA_{BC_0}). Similarly, the deserializer circuitry 1440 may transmit a second serial data stream to the serializer circuitry 1430 using a back channel of the communication channel 1255B. The data of the second serial data stream is referred to as second back channel data (DATA_{BC_1}). In such examples, the first and second front channel data has a data rate greater than the first and second back channel data to reduce interference. Such multi-directional communications along the communication channels 1255A, 1255B are referred to as full-duplex communications. The deserializer circuitry 1440 may use the back channel of the communication channels 1255A, 1255B to verify reception of the first and second front channel data, report errors to the programmable circuitry 1420, etc. Similarly, the display driver 1270 and the serializer circuitry 1470 may utilize full-duplex communications along the communication channels 1255C, 1255D to exchange third and fourth front channel data (DATA_{FC_2}, DATA_{FC_3}) and third and fourth back channel data (DATA_{BC_2}, DATA_{BC_3}).

In example operation, the deserializer circuitry 1440 deserializes the first and second front channel data to produce multiple parallel data paths. The decoder circuitry 1450 decodes the data from the media source 1245 from the additional data from the programmable circuitry 1420. The decoder circuitry 1450 determines which one or more of the displays 1260, 1265, 1275 correspond to the data from the media source 1245 responsive to the decoded data. In some examples, the decoder circuitry 1450 supplies the multiple parallel data paths to the serializer circuitry 1470 responsive to a determination that the media does not correspond to the displays 1260, 1265. In such examples, the serializer circuitry 1470 serializes and transmits the third and fourth front channel data to the display driver 1270. Advantageously, the display driver 1270 may be coupled in series with another instance of the display driver 1270 by additional communication channels, such as a fifth and sixth communication channel.

In example operation, the decoder circuitry supplies the multiple parallel data paths to the display interface 1460 responsive to a determination that the media from the media source 1245 corresponds to at least one of the displays 1260, 1265. In some examples, the display interface 1460 structures the data from the decoder circuitry 1450 to drive one or more of the displays 1260, 1265. In some examples, the display interface 1460 is at least one of a column pixel driver or a row pixel driver. In such examples, at least one of the displays 1260, 1265 produce a perceivable representation of the media from the media source 1245 responsive to the display interface 1460.

Example operations of the serializer and deserializer system of the IVI system 1210 are further described in connection with FIG. 15. Advantageously, serializing and deserializing data from the media source 1245 reduces the number of connections to one or more of the displays 1260, 1265, 1275. Also, the serial data streams are capable of accurately traversing relatively large distances across the communication channels 1255A, 1255B, 1255C, 1255D.

FIG. 15 is a block diagram of an example serial-deserializer (SerDes) system 1500 including example deserializer circuitry 1505 and example serializer circuitry 1510. The example deserializer circuitry 1505 of FIG. 15 includes an example serializer 1515, example transmitter circuitry 1520, example receiver circuitry 1525, and example clock and data recovery (CDR) circuitry 1530. The example CDR circuitry 1530 of FIG. 15 includes example retimer circuitry 1535 and an example deserializer 1540. The example serializer circuitry 1510 of FIG. 15 includes an example serializer 1545, example transmitter circuitry 1550, example receiver circuitry 1555, example CDR circuitry 1560, and example decoder circuitry 1565. The example CDR circuitry 1560 of FIG. 15 includes example retimer circuitry 1570 and an example deserializer 1575.

The SerDes system 1500 includes an interface between the deserializer circuitry 1505 and the serializer circuitry 1510 in both the ADAS system 1205 of FIGS. 12 and 13 and the IVI system 1210 of FIGS. 12 and 14. In the example of the ADAS system 1205 of FIG. 13, the deserializer circuitry 1505 represents the deserializer circuitry 1310 in the ADAS hub 1215 and the serializer circuitry 1510 represents the serializer circuitry 1345 in the peripheral module 1220. In the example of the IVI system 1210 of FIG. 14, the deserializer circuitry 1505 represents the deserializer circuitry 1440 in the display driver 1255. Also, in the example of the IVI system 1210 of FIG. 14, the serializer circuitry 1510 represents the serializer circuitry 1430 in the IVI driver circuitry 1250 or the serializer circuitry 1470 in the display driver 1255.

The deserializer circuitry 1505 is coupled to the serializer circuitry 1510 by the communication channel 1510A. The deserializer circuitry 1505 has inputs (DATA_IN_{BC}) and outputs (DATA_OUT_{FC}). The inputs and outputs of the deserializer circuitry 1505 are structured to be coupled to one of the programmable circuitry 1335 of FIG. 13 or the decoder circuitry 1450 of FIG. 14. The inputs of the deserializer circuitry 1505 receive back-channel data for transmission along the communication channel 1510A. The outputs of the deserializer circuitry 1505 provide front channel data from the communication channel 1510A.

The serializer circuitry 1510 is coupled to the deserializer circuitry 1505 by the communication channel 1510A. The serializer circuitry 1510 has inputs (DATA_IN_{FC}) and outputs (DATA_OUT_{BC}). The inputs and outputs of the serializer circuitry 1510 are structured to be coupled to one of the sensor 1355 of FIG. 13 or the programmable circuitry 1420 of FIG. 14. The inputs of the serializer circuitry 1510 receive front channel data for transmission along the communication channel 1510A. The outputs of the serializer circuitry 1510 provide back channel data from the communication channel 1510A.

The serializer 1515 has inputs and an output. The inputs of the serializer 1515 are coupled to the inputs of the deserializer circuitry 1505 (DATA_IN_{BC}). The output of the serializer 1515 is coupled to the transmitter circuitry 1520. In some examples, the serializer 1515 is referred to as a back channel serializer.

The transmitter circuitry 1520 has an input and an output. The input of the transmitter circuitry 1520 is coupled to the serializer 1515. The output of the transmitter circuitry 1520 is coupled to the communication channel 1510A and the receiver circuitry 1525. In some examples, the transmitter circuitry 1520 is referred to as a back channel transmitter.

The receiver circuitry 1525 has an input and an output. The input of the receiver circuitry 1525 is coupled to the communication channel 1510A and the transmitter circuitry 1520. The output of the receiver circuitry 1525 is coupled to the CDR circuitry 1530. In some examples, the receiver circuitry 1525 is referred to as a front channel receiver.

The CDR circuitry 1530 has an input and outputs. The input of the CDR circuitry 1530 is coupled to the receiver circuitry 1525. The outputs of the CDR circuitry 1530 are coupled to the outputs of the deserializer circuitry 1505 (DATA_OUT_{FC}). In some examples, the CDR circuitry 1530 is referred to as front channel CDR circuitry. In some examples, the CDR circuitry 1560 implements the PLL circuitry 104 or 904 described herein.

The retimer circuitry 1535 has an input, a first output, and a second output. The input of the retimer circuitry 1535 is coupled to the receiver circuitry 1525. The first and second outputs of the retimer circuitry 1535 are coupled to the deserializer 1540. An example of the retimer circuitry 1535 is further illustrated and described in connection with FIG. 5.

The deserializer 1540 has a first input, a second input, and outputs. The first and second inputs of the deserializer 1540 are coupled to the retimer circuitry 1535. The outputs of the deserializer 1540 are coupled to the outputs of the deserializer circuitry 1505 (DATA_OUT_{FC}).

The serializer 1545 has inputs and an output. The inputs of the serializer 1545 are coupled to the inputs of the serializer circuitry 1510 (DATA_IN_{FC}). The output of the serializer 1545 is coupled to the transmitter circuitry 1550. In some examples, the serializer is referred to as a front channel serializer.

The transmitter circuitry 1550 has an input and an output. The input of the transmitter circuitry 1550 is coupled to the serializer 1545. The output of the transmitter circuitry 1550 is coupled to the communication channel 1510A and the receiver 1555. In some examples, the transmitter circuitry 1550 is referred to as a front channel transmitter. The transmitter circuitry 1520, 1550 may include circuitry to impedance match the communication channel 1510A to reduce reflections. Also, the transmitter circuitry 1520, 1550 may have different bandwidths.

The receiver circuitry 1555 has an input and an output. The input of the receiver circuitry 1555 is coupled to the communication channel 1510A and the transmitter circuitry 1550. The output of the receiver circuitry 1555 is coupled to the CDR circuitry 1560. In some examples, the receiver circuitry 1555 is referred to as a back channel receiver.

The CDR circuitry 1560 has an input and outputs. The input of the CDR circuitry 1560 is coupled to the receiver circuitry 1555. The outputs of the CDR circuitry 1560 are coupled to the decoder circuitry 1565. In some examples, the CDR circuitry 1560 is referred to as back channel CDR circuitry. In some examples, the CDR circuitry 1560 implements the PLL circuitry 104 or 904 described herein.

The decoder circuitry 1565 has inputs and outputs. The inputs of the decoder circuitry 1565 are coupled to the CDR circuitry 1560. The outputs of the decoder circuitry 1565 are coupled to the outputs of the serializer circuitry 1510 (DATA_OUT_{BC}). In some examples, as illustrated by the dashed lines, the outputs of the CDR circuitry 1560 are directly coupled to the outputs of the serializer circuitry 1510 (DATA_OUT_{BC}).

The retimer circuitry 1570 has an input, a first output, and a second output. The input of the retimer circuitry 1570 is coupled to the receiver circuitry 1555. The first and second outputs of the retimer circuitry 1570 are coupled to the deserializer circuitry 1575. An example of the retimer circuitry 1570 is further illustrated and described in connection with FIG. 5.

The deserializer 1575 has a first input, a second input, and outputs. The first and second inputs of the deserializer 1575 are coupled to the retimer circuitry 1570. The outputs of the deserializer 1575 are coupled to the decoder circuitry 1565. In some examples, as illustrated by the dashed lines, the outputs of the deserializer 1575 are directly coupled to the outputs of the serializer circuitry 1510 (DATA_OUT_{BC}).

In example operation, the deserializer circuitry 1505 receives back channel data (DATA_{BC}) via multiple data paths from an external data source, such as the programmable circuitry 1335 or the decoder circuitry 1450. The serializer 1515 produces a back channel serial data stream responsive to the back channel data. The transmitter circuitry 1520 transmits the back channel data to the serializer circuitry 1510 across the communication channel 1510A. Similarly, the serializer circuitry 1510 receives front channel data (DATA_{FC}) via multiple data paths from an external data source, such as the sensor 1355 or the programmable circuitry 1420. The serializer 1545 produces a front channel serial data stream responsive to the front channel data. The transmitter circuitry 1520 transmits the front channel data to the deserializer circuitry 1505 across the communication channel 1510A. In some examples, the data rates of the transmissions of the front and back channel data are different to prevent interference. In some examples, the bandwidth of the transmitter circuitry 1520, which transmits the back channel data, is modified to reduce non-linear gain contributions of the communication channel 1510A. Advantageously, the serializers 1515, 1545 and the transmitter circuitry 1520, 1550 support full-duplex data transmissions along the communication channel 1510A.

In example operation, the deserializer circuitry 1505 receives the front channel data (DATA_{FC}) after propagating along the communication channel 1510A. The receiver circuitry 1525 produces a serial data stream representing the front channel data responsive to signals from the communication channel 1510A. In some examples, the receiver circuitry 1525 isolates the communication channel 1510A from the CDR circuitry 1530. The deserializer circuitry 1505 may include echo cancelation circuitry to reduce contributions of the back channel data from signals received by the transmitter circuitry 1520. Similarly, the serializer circuitry 1510 receives the back channel data (DATA_{BC}) after propagating along the communication channel 1510A. The receiver circuitry 1555 produces a serial data stream representing the back channel data responsive to signals from the communication channel 1510A. In some examples, the receiver circuitry 1525 isolates the communication channel 1510A from the CDR circuitry 1530. The serializer circuitry 1510 may include echo cancelation circuitry to reduce contributions of the front channel data from signals received by the transmitter circuitry 1550. Also, the receiver circuitry 1525, 1555 terminate currents of the communication channel 1510A.

In example operation, the CDR circuitry 1530 receives the front channel data from the receiver circuitry 1525. The retimer circuitry 1535 retimes the front channel data to produce retimed front channel data (RETIMED_DATA). The retimer circuitry 1535 produces a clock signal (CLK), which represents an accurate sampling time of the retimed front channel data. The deserializer 1540 receives the retimed front channel data and the clock signal from the retimer circuitry 1535. The deserializer 1540 produces multiple parallel data paths representing the front channel data. The outputs of the deserializer circuitry 1505 provide the front channel data to external circuitry, such as the programmable circuitry 1335 or the decoder circuitry 1450. Similarly, the CDR circuitry 1560 receives the back channel data from the receiver circuitry 1555. The retimer circuitry 1535 produces retimed back channel data and a clock signal responsive to the retiming of the back channel data to the clock signal. The deserializer 1575 receives the retimed back channel data and the clock signal from the retimer circuitry 1570. The deserializer 1575 produces multiple parallel data paths representing the back channel data. In some such example operations, the decoder circuitry 1565 decodes portions of the back channel data prior to the outputs of the serializer circuitry 1510 supplying the back channel data to external circuitry, such as the sensor 1355 or the programmable circuitry 1420.

Example operations of the clock generation operations of the CDR circuitry 1530 and 1560 are further illustrated and described above with respect to the PLL circuitry 104 and 904. Advantageously, serializing and deserializing front and back channel data reduces the number of connections that need to traverse relatively large distances of the communication channel 1510A. Advantageously, the serial data streams are capable of accurately traversing relatively large distances across the communication channels 1510A.

“Including” and “comprising” (and all forms and tenses thereof) are used herein to be open ended terms. Thus, whenever a claim employs any form of “include” or “comprise” (for example, comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (for example, “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, for example, the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (for example, attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (for example, within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (for example, wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (for example, an application specific circuit (ASIC)) structured to perform specific operation(s) and including one or more semiconductor-based logic devices (for example, electrical hardware implemented by one or more transistors), or (ii) one or more general purpose semiconductor-based electrical circuits programmable with instructions to perform one or more specific functions(s) or operation(s) and including one or more semiconductor-based logic devices (for example, electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (for example, one or more FPGAs, one or more CPUs, one or more GPUs, one or more NPUs, one or more DSPs, etc., and any combination(s) thereof), and orchestration technology (for example, application programming interface(s) (API(s)) that may assign computing task(s) to whichever one(s) of the multiple types of programmable circuitry is/are suited and available to perform the computing task(s).

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (for example, at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and current sources) may instead include only the semiconductor elements within a single physical device (for example, at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. Phase locked loop (PLL) circuitry comprising:
sampler circuitry having a first input to receive a reference clock signal (CLKM_REF) a second input to receive a feedback clock signal (CLKB_FBK), and an output;
transconductor circuitry having an input coupled to the output of the sampler circuitry and having an output;
filter circuitry having an input coupled to the output of the transconductor circuitry and having an output;
voltage controlled oscillator (VCO) circuitry having an input coupled to the output of the filter circuitry and having an output; and
frequency divider circuitry having an input coupled to the output of the VCO circuitry and having an output coupled to the second input of the sampler circuitry.

2. The PLL circuitry of claim 1, further including:
a resistor having a first terminal coupled to the output of the transconductor circuitry and a second terminal; and
a capacitor having a first terminal coupled to the second terminal of the resistor and having a second terminal configured to receive a supply voltage.

3. The PLL circuitry of claim 1, wherein:
the input of the frequency divider circuitry is a first input; and
the PLL circuitry further includes Delta Sigma Modulation (DSM) circuitry having an input coupled to the output of the frequency divider circuitry and having an output coupled to a second input of the frequency divider circuitry.

4. The PLL circuitry of claim 1, wherein:
the reference clock signal is an original reference clock signal; and
the sampler circuitry further includes extender circuitry and switch capacitor filter (SCF) circuitry.

5. The PLL circuitry of claim 4, wherein the extender circuitry includes:
a first resistor having a first terminal and a second terminal;
a first transistor having a source terminal coupled to the second terminal of the first resistor, a control terminal configured to receive the original reference clock signal, and a drain terminal coupled to the SCF circuitry;
a second transistor having a source terminal coupled to the SCF circuitry and the drain terminal of the first transistor, a control terminal configured to receive the original reference clock signal, and a drain terminal; and
a second resistor having a first terminal coupled to the drain terminal of the second transistor and a second terminal configured to receive a second supply voltage.

6. The PLL circuitry of claim 4, wherein the extender circuitry includes:
a first resistor having a first terminal;
a first transistor having a source terminal coupled to the second terminal of the first resistor, a control terminal, and a drain terminal that is coupled to the control terminal;
a first capacitor having a first terminal and a second terminal coupled to the control terminal of the first transistor;
a first switch having a first terminal coupled to the control terminal of the first transistor, a control terminal, and a second terminal;
a second switch having a first terminal, a control terminal, and a second terminal coupled to the second terminal of the first switch;
a second resistor having a first terminal and a second terminal;
a second transistor having a source terminal coupled to the second terminal of the second resistor, a control terminal coupled to the second terminal of the first switch and the second terminal of the second switch, and a drain terminal coupled to the SCF circuitry;
a third transistor having a source terminal coupled to the SCF circuitry and the drain terminal of the second transistor, a control terminal, and a drain terminal;
a third resistor having a first terminal coupled to the drain terminal of the third transistor and a second terminal;
a third switch having a first terminal coupled to the control terminal of the third transistor, a control terminal, and a second terminal;
a fourth switch having a first terminal coupled to the control terminal of the third transistor, a control terminal, and a second terminal;
a second capacitor having a first terminal coupled to the second terminal of the fourth switch and a second terminal;
a fourth transistor having a source; a control terminal coupled to both the source terminal of the fourth transistor and the second terminal of the fourth switch, and a drain terminal; and
a fourth resistor having a first terminal coupled to the drain terminal of the fourth transistor and a second terminal.

7. The PLL circuitry of claim 4, wherein the extender circuitry includes:
a current source having a first terminal and a second terminal;
a first transistor having a source terminal coupled to the current source, a control terminal coupled to the original reference clock signal, and a drain terminal;
a first switch having a first terminal coupled to the drain terminal of the first transistor, a control terminal, and a second terminal;
a first capacitor having a first terminal coupled to the second terminal of the first switch and a second terminal;
a second transistor having a source terminal coupled to the drain terminal of the first transistor, a control terminal, and a drain terminal;
a third transistor having a source terminal coupled to the current source, a control terminal coupled to the original reference clock signal, and a drain terminal;
a second switch having a first terminal coupled to the drain terminal of the first transistor, a control terminal, and a second terminal;
a second capacitor having a first terminal coupled to the second terminal of the second switch and a second terminal;
a fourth transistor having a source terminal coupled to the drain terminal of the third transistor, a control terminal, and a drain terminal;
a resistor having a first terminal coupled to the drain terminal of the first transistor and a second terminal;
a third switch having a first terminal coupled to the drain terminal of the first transistor, a control terminal, and a second terminal coupled to the drain terminal of the third transistor;
a third capacitor having a first terminal coupled to the drain terminal of the second transistor and a second terminal coupled to the drain terminal of the first transistor; and
common mode feedback (CMFB) circuitry having a first terminal coupled to the drain terminal of the first transistor, a second terminal coupled to the drain terminal of the third transistor, and a third terminal coupled to the drain terminals of both the third and fourth transistors.

8. The PLL circuitry of claim 4, wherein the SCF circuitry includes:
a first switch having a first terminal coupled to the extender circuitry, a control terminal, and a second terminal;
a first capacitor having a first terminal coupled to the second terminal of the first switch and a second terminal;
a second switch having a first terminal coupled to the second terminal of the first switch, a control terminal and a second terminal coupled to the transconductor circuitry; and
a second capacitor having a first terminal coupled to the second terminal of the second switch and a second terminal.

9. The PLL circuitry of claim 4, wherein the SCF circuitry includes:
a first switch having a first terminal coupled to the extender circuitry, a control terminal, and a second terminal;
a first capacitor having a first terminal coupled to the second terminal of the first switch and a second terminal;
a second switch having a first terminal coupled to the second terminal of the first capacitor, a control terminal, and a second terminal;
a third switch having a first terminal coupled to the second terminal of the first capacitor, a control terminal, and a second terminal;
a fourth switch having a first terminal coupled to the second terminal of the first switch, a control terminal, and a second terminal coupled to the transconductor circuitry;
a second capacitor having a first terminal coupled to the second terminal of the first switch and a second terminal; and
a third capacitor having a first terminal coupled to the second terminal of the fourth switch and a second terminal.

10. Phase locked loop (PLL) circuitry comprising:
sampler circuitry having a first input to receive a reference clock signal (CLKM_REF), a second input to receive a feedback clock signal (CLKB_FBK), and an output;
transconductor circuitry having an input coupled to the output of the sampler circuitry and having an output;
auxiliary phase frequency detector (AUX PFD) circuitry having a first input to receive the reference clock signal, a second input to receive the feedback clock signal, and an output;
reduced charge pump (RCP) circuitry having an input coupled to the AUX PFD circuitry and an output;
filter circuitry having a first input coupled to the output of the transconductor circuitry, a second input coupled to the output of the RCP circuitry, and an output; and
voltage controlled oscillator (VCO) circuitry having an input coupled to the output of the filter circuitry and having an output.

11. The PLL circuitry of claim 10, further including:
a resistor having a first terminal coupled to the output of the transconductor circuitry and a second terminal; and
a capacitor having a first terminal coupled to the second terminal of the resistor and having a second terminal.

12. The PLL circuitry of claim 10, further including:
frequency divider circuitry having an input coupled to the output of the VCO circuitry and having an output coupled to the second input of the sampler circuitry; and
Delta Sigma Modulation (DSM) circuitry having an input coupled to the output of the frequency divider circuitry and having an output coupled to a second input of the frequency divider circuitry.

13. The PLL circuitry of claim 10, wherein the AUX PFD circuitry is configured to quantify a phase error between the reference clock signal and the feedback clock signal.

14. The PLL circuitry of claim 13, wherein the RCP circuitry is configured to pump an amount of current into the filter circuitry based on a polarity of the phase error.

15. The PLL circuitry of claim 10, further including counter circuitry.

16. The PLL circuitry of claim 10, wherein:
the RCP circuitry includes a main path for current to flow formed by a current source, an up switch, a down switch, and a current sink; and
the RCP circuitry does not include a dummy path for the current to flow through.

17. The PLL circuitry of claim 10, wherein the AUX PFD circuitry and the RCP circuitry implement an auxiliary path with hysteresis control.

18. An apparatus comprising:
extender circuitry including:
a current source having a first terminal and a second terminal;
a first transistor having a source terminal coupled to the current source, a control terminal coupled to the original reference clock signal, and a drain terminal;
a first switch having a first terminal coupled to the drain terminal of the first transistor, a control terminal, and a second terminal;
a first capacitor having a first terminal coupled to the second terminal of the first switch and a second terminal;
a second transistor having a source terminal coupled to the drain terminal of the first transistor, a control terminal, and a drain terminal;
a third transistor having a source terminal coupled to the current source, a control terminal coupled to the original reference clock signal, and a drain terminal;
a second switch having a first terminal coupled to the drain terminal of the first transistor, a control terminal, and a second terminal;
a second capacitor having a first terminal coupled to the second terminal of the second switch and a second terminal;
a fourth transistor having a source terminal coupled to the drain terminal of the third transistor, a control terminal, and a drain;
a resistor having a first terminal coupled to the drain terminal of the first transistor and a second terminal;
a third switch having a first terminal coupled to the drain terminal of the first transistor, a control terminal, and a second terminal coupled to the drain terminal of the third transistor;
a third capacitor having a first terminal coupled to the drain terminal of the second transistor and a second terminal coupled to the drain terminal of the first transistor; and
common mode feedback (CMFB) circuitry having a first terminal coupled to the drain terminal of the first transistor, a second terminal coupled to the drain terminal of the third transistor, and a third terminal coupled to the drain terminals of both the third and fourth transistors; and
switch capacitor filter circuitry including:
a first capacitor having a first terminal coupled to the second terminal of the first switch and a second terminal;
a second switch having a first terminal coupled to the second terminal of the first capacitor, a control terminal and a second terminal;
a third switch having a first terminal coupled to the second terminal of the first capacitor, a control terminal, and a second terminal;
a fourth switch having a first terminal coupled to the second terminal of the first switch, a control terminal and a second terminal coupled to an output of transconductor circuitry;
a second capacitor having a first terminal coupled to the second terminal of the first switch and a second terminal; and
a third capacitor having a first terminal coupled to the second terminal of the fourth switch and a second terminal.

19. The apparatus of claim 18, wherein the extender circuitry is configured to generate clock signals that oscillate around a common mode voltage by steering current from the current source to one of the first capacitor or the second capacitor.

20. The apparatus of claim 19, wherein:
the first capacitor within the switch capacitor filter circuitry is configured to generate an offset voltage to the second capacitor; and
sample the generated clock signals earlier in time based on the offset voltage.
